(19) United States
(12) Patent Application Publication
(10) Pub. No.: US 2024/0311673 A1
(43) Pub. Date: Sep. 19, 2024

(54) CRYOGENIC CLASSICAL SUPERCONDUCTING CIRCUITRY FOR ERROR CORRECTION IN QUANTUM COMPUTING

(71) Applicants: SeeQC, Inc., Elmsford, NY (US); 1QB Information Technologies Inc., Vancouver (CA)

(72) Inventors: Amir Jafari Salim, Yonkers, NY (US); Caleb Jordan, Peekskill, NY (US); Matthew Hutchings, Surrey (GB); Oleg Mukhanov, Putnam Valley, NY (US); Pooya Ronagh, Vancouver (CA); Krishanu Roy Sankar, Vancouver (CA); Navid Ghadermarzy, Vancouver (CA)

(21) Appl. No.: 18/274,442

(22) PCT Filed: Jan. 27, 2022
(86) PCT No.: PCT/US22/14154

§ 371 Date: Jul. 26, 2023

Related U.S. Application Data
(60) Provisional application No. 63/142,375, filed on Jan. 27, 2021.

(51) Int. Cl. G06N 10/40; G06N 10/70; H10N 60/12

(52) U.S. Cl. CPC G06N 10/40; G06N 10/70; H10N 60/12

(57) ABSTRACT

This patent document is directed to implementations of embodiments of an error correction module or gadget using a cryogenic classical superconducting circuit that can be used as a decoder of quantum error correcting codes correcting errors in quantum computing.

### PRIORITY CLAIM AND RELATED PATENT APPLICATION

This patent document claims the priority and benefits of U.S. Provisional Patent Application No. 63/142,375 entitled “CRYOGENIC CLASSICAL SUPERCONDUCTING CIRCUITRY FOR ERROR CORRECTION IN QUANTUM COMPUTING” by Applicants SeeQC, Inc. and 1QB Information Technologies Inc. on Jan. 27, 2021 under Attorney Docket No. 133858-8007.US00.

### TECHNICAL FIELD

The disclosure of this patent document relates to error correction in transmission of signals and data in quantum computing systems.

### BACKGROUND

In digital computing and transmission of digital signals or data in communication systems, transmitted digital data may be subject to errors during transmission from a sender to a receiver. An error correction code or error correcting code (ECC) may be used to encode digital data to be transmitted for controlling errors in data over a communication channel from the sender to the receiver. The sender encodes the message or data to be transmitted with redundant information so that errors that may occur in the transmission can be detected and corrected without retransmission.

In quantum computing, a quantum system for performing quantum computations can be implemented by an ensemble of subsystems exhibiting different quantum states where subsystems are correlated or “entangled” with one another due to quantum coherence. In various implementations, each subsystem in the ensemble of subsystems may exhibit two or more different quantum states to operate as a fundamental quantum device. Information can be represented, stored, processed, and transmitted by superposition and correlation of quantum states of different fundamental quantum devices. Such a fundamental quantum device with two or more different quantum states may be referred to as a “qudit” and a two-state device is often referred to as a quantum bit (“qubit”). In quantum computing, in addition to errors which may occur during data transmission in the digital computing, quantum information is vulnerable to errors due to quantum decoherence and other quantum noise or interference. Quantum error correction is essential to achieve fault tolerant quantum computing and is an integrated part of quantum computing.

### SUMMARY

The disclosure of this patent document is directed to implementations of embodiments of an error correction module or gadget using a cryogenic classical superconducting circuit that can be used as a decoder of quantum error correcting codes correcting errors in quantum computing.

Methods and systems disclosed herein replace the classical decoder by a function approximator of the true decoding function. The function approximator is produced by pre-training a model on data generated by a decoder in simulation or in a quantum experiment. An example of such a model is a neural network. Such a function approximator can reach the decoding accuracy near that of a classical decoder, but uses much simpler and faster logic. As a result, the function approximator (1) can be implemented on hardware which can operate within the dilution refrigerator or another cryogenic environment, removing latency time and potential errors in data transfer to and from the quantum processor, and (2) uses much less processing time than a classical decoder.

The disclosed cryogenic classical superconducting circuit may be implemented to use superconducting Josephson Junction electronics to process the information. Superconducting electronics operate at high speed with low energy dissipation. The disclosed cryogenic classical superconducting circuit may include digital and mixed-signal single quantum flux families such as rapid single flux quantum (RSFQ), energy efficient rapid single flux quantum (ERSFQ), energy efficient single flux quantum (eSFQ), reciprocal quantum logic (RQL), and quantum parametron circuits such as adiabatic quantum flux parametron (AQFP), a superconducting quantum interface device (SQUID), a Bi-SQUID with two Josephson junctions, a SQUID with negative mutual inductance (nSQUID), etc. as well as analogue superconducting circuits based on SQUIDs.

In one implementation, the disclosed technology can be implemented to provide a system for quantum computing and capable of quantum error correction to include a cryogenic device structured to include different cryogenic stages at different cryogenic temperatures; a quantum processor comprising a plurality of qudits to perform quantum computing, the plurality of qudits comprising data qudits and syndrome qudits to interact with the data qudits to provide measurements of the syndrome qudits, wherein the plurality of qudits comprises an error correcting code for correcting quantum errors in the quantum computing; the quantum processor is coupled to and cooled by the cryogenic device at a desired cryogenic temperature for proper operations of the qudits; and a cryogenic classical superconducting circuit coupled to and cooled by the cryogenic device, and further coupled to receive information on the measurements from the syndrome qudits, and structured to include a decoder of the quantum error correcting code to process the received information on the measurements from the syndrome qudits and to generate a recovery operation for data qudits to reduce errors in the quantum computing, wherein the cryogenic classical superconducting circuit is coupled as a classical coprocessor to the quantum processor to reduce a communication lag between the quantum processor and the cryogenic classical superconducting circuit.

In another implementation, the disclosed technology can be implemented to provide a method for implementing a quantum error correction scheme which includes preparing the at least one syndrome qudit; performing the at least one syndrome extraction circuit comprising at least one data qudit and at least one syndrome qudit; performing at least one measurement on the at least one syndrome qudit of each the syndrome extraction circuit; providing results of the at least one measurement to the function approximator of the decoder; using the function approximator of the decoder to provide a recovery operation comprising a recovery operator; and applying the recovery operation.

In another implementation, the disclosed technology can be implemented to provide a cryogenic classical superconducting circuit functioning at cryogenic temperatures comprising: a function approximator for a decoder of quantum error correcting codes, wherein the decoder comprises a plurality of nodes, a plurality of interconnects between nodes of the plurality of nodes for distributing pulses between the nodes, and a plurality of weights representative of the function approximator parameters, wherein each node of the plurality of nodes comprises a receiver section to receive at least one pulse comprising a magnetic flux, current, or voltage; a processing core to process the received pulse; and a transmitter section to transmit the processed pulse.

In another implementation, the disclosed technology can be implemented to provide a method for constructing the function approximator for a decoder to perform operations that include collecting data on at least one syndrome qudits and on corresponding errors from the error correcting code; and using the collected data on the at least one syndrome qudits and the collected data on the corresponding errors to construct the function approximator.

In yet another implementation, the disclosed technology can be implemented to provide a quantum computing system that includes a quantum processor comprising a plurality of physical qudits each capable of exhibiting different quantum states, the plurality of physical qudits structured to perform quantum computing and to comprise a plurality of data qudits to perform quantum computing and a plurality of syndrome qudits located amongst the data qudits to interact with the data qudits to provide measurements of quantum states of the syndrome qudits that are indicative of quantum errors in the quantum computing performed by the quantum processor; qudit readout circuits coupled to the quantum processor to interact with the syndrome qudits and to produce readout signals representing measurements of quantum states of the syndrome qudit; a cryogenic classical superconducting circuit coupled to receive information of the readout signals representing measurements of quantum states of the syndrome qudits, the cryogenic classical superconducting circuit structured to include a decoder that processes the received information to obtain information on errors in the quantum computing performed by the quantum processor and generates a recovery operation for reconstructing quantum information of the qudits to reduce the errors in the quantum computing; and a cryogenic system coupled to enclose the quantum processor, the qudit readout circuits and the cryogenic classical superconducting circuit at desired cryogenic temperatures, respectively, wherein the cryogenic classical superconducting circuit and the quantum processor are positioned relative to each other to enable fast communications between the cryogenic classical superconducting circuit and the quantum processor with a reduced communication lag.

An advantage of one or more embodiments of the disclosed technology is that it removes or substantially reduces the time latency of data transfer between the quantum processor and the classical co-processor.

Another advantage of one or more embodiments of the disclosed technology is that it prevents potential errors in data transfer between the quantum processor and the classical co-processor.

Another advantage of one or more embodiments of the disclosed technology is that the function approximator may be implemented on hardware which may be placed and operated in the dilution refrigerator or another cryogenic cooling device.

Another advantage of one or more embodiments of the disclosed technology is that it can be applied to various quantum processors and various quantum computations.

Another advantage of one or more embodiments of the disclosed technology is that it can utilize various function approximators and in particular various neural networks.

Another advantage of one or more embodiments of the disclosed technology is that it reduces processing time compared to a conventional decoder.

Another advantage of one or more embodiments of the disclosed technology is that the decoder can be trained in a data-driven fashion using the data stream collected from the experiments run on the system.

Another advantage of one or more embodiments of the disclosed technology is that the decoder can be re-tuned or calibrated according to the data stream from the experiments run on a latest window of time, therefore providing most performance according to the latest sources of noise afflicting the qudits of the system.

The above and other features of the disclosed technology are described in greater detail in the drawings, the description and the claims.

### BRIEF DESCRIPTION OF THE DRAWINGS

FIG. 1 is a diagram of an example of a cryogenic classical superconducting circuit comprising at least one function approximator for a decoder of quantum error correcting codes based on one implementation of the disclosed technology.

FIG. 2 is a diagram of a node of the decoder described in FIG. 1.

FIG. 3 is a diagram of an embodiment of a node receiver.

FIG. 4 is a diagram showing an embodiment of a variable weight implementation wherein the weights are encoded in the number of generated SFQ pulses.

FIG. 5 shows two embodiments of variable multi pulse generator.

FIG. 6 is a diagram showing an embodiment of a node processing core with an activation function based on a threshold.

FIG. 7A is a diagram showing an embodiment of a node processing core with a rectified linear unit (ReLU) activation function using SQUID.

FIG. 7B is a diagram showing an embodiment of a node processing core with a rectified linear unit (ReLU) activation function using Bi-SQUID.

FIG. 8 is a diagram showing two embodiments of clearing the stored flux and resetting the circuit.

FIG. 9 is a diagram showing an embodiment of a direct one-to-one interconnect.

FIG. 10 is a diagram showing an embodiment of connectivity between nodes of two layers.

FIG. 11 is a diagram showing an embodiment of connectivity between nodes in two consecutive layers using parallelizers and serializers to reduce the number of interconnect wires.

FIG. 12 is a diagram of an embodiment of a quantum correction gadget.

FIG. 13 is a flowchart that shows an embodiment of a method for implementing a quantum error correction scheme using the system described in FIG. 12.

FIG. 14 is a flowchart that shows an embodiment of a method for constructing a function approximator for a decoder of quantum error correcting codes.

FIG. 15 is a diagram showing an embodiment of a buffer with coupling and a D flip-flop buffer function for storing incoming signals.

FIG. 16 is a diagram showing an embodiment of a variable coupling.

FIG. 17 is a diagram showing an embodiment of amplifiers locations for a node.

FIG. 18 is a diagram showing an embodiment of an amplifier with multi SQUIDs in series.

FIG. 19 is a diagram showing an embodiment of an analog node.

### DETAILED DESCRIPTION

Error correction in quantum computers is desirable in order to provide fault-tolerant quantum computations and to perform large-scale quantum algorithms for solving computational problems which may be intractable for conventional computers.

A physical quantum device qubit or qudit in a quantum computer may suffer from continuous errors as a result of various sources, such as natural decoherence or an interaction with a control apparatus. One approach to overcoming these errors is by using quantum error correction schemes, where a single logical qubit or qudit is encoded using a combination of (1) a number of physical qubits or qudits for performing the quantum computations, (2) additional syndromes qubits or qudits and error correction circuitry to detect errors in the quantum states of physical qubits or qudits performing the quantum computations, (3) a decoder which prescribes recovery operations on the basis of observed syndromes, and (4) a controller to apply the recovery operations to the physical qubits or qudits. Fault-tolerance is achieved when errors can be detected and corrected at a faster rate than they accrue, thereby preventing errors from compounding over long computations.

However, engineering such a quantum error correction system presents challenges. The complexity increases exponentially with the increasing number of error possibility to be corrected. The decoding needs to be done in a short period of time to enable actions needed to correct errors. Performing decoding quickly in a decoder and locating the decoder as close to qubits or qudits as possible can reduce undesired latency caused by error correction operations. The decoding process can be implemented by a classical co-processor that is located adjacent to the quantum processor formed by qubits or qudits, and to perform the decoding process on the same timeframe as the rate at which errors are generated. For superconducting qubits or qudits which have very short decoherence times and very fast gates, this fast decoding time can be difficult or challenging to achieve because of (1) the latency time required to transmit readout information between the quantum processor and classical co-processor, and (2) the processing time required to perform the decoding.

The technology disclosed in this patent document can be implemented in ways to provide a method and a system to mitigate certain limitations associated with the accuracy of physical qubits or qudits, the communication lag between a quantum processor and classical co-processor and the speed limitation of error-correction.

The disclosed technology can be implemented to include, for example, a system for performing quantum computing and capable of quantum error correction that includes a cryogenic device structured to include different cryogenic stages at different cryogenic temperatures and a quantum processor comprising a plurality of qudits to perform quantum computing and is coupled to and cooled by the cryogenic device at a desired cryogenic temperature for proper operations of the qudits. The qudits include (1) data qudits to encode quantum information for the quantum computing and (2) syndrome qudits to interact with the data qudits to provide measurements of the syndrome qudits. The combination of the data qudits and syndrome qudits provides or enables a quantum error correcting code for correcting quantum errors in the quantum computing. This system further includes a cryogenic classical superconducting circuit coupled to and cooled by the cryogenic device. The cryogenic classical superconducting circuit is coupled to receive information on the measurements from the syndrome qudits, and structured to include a decoder of the quantum error correcting code to process the received information on the measurements from the syndrome qudits and to generate a recovery operation for data qudits to reduce errors in the quantum computing. The cryogenic classical superconducting circuit is coupled as a classical coprocessor to the quantum processor to reduce a communication lag between the quantum processor and the cryogenic classical superconducting circuit.

In implementations, the cryogenic classical superconducting circuit may include classical circuits that interface with the data qudits and syndrome qudits. The part of the classical circuits that interface with syndrome qudits includes a decoder for solving the decoding problem and for generating a recovery operation for each corresponding data qudit in correcting errors in the quantum computing. For example, in some implementations, the decoder may be constructed based on neural networks.

As used herein, the term “qubit” generally refers to a unit of quantum information processing whose quantum state is a complex unit vector of dimension 2. These two dimensions are typically referred to as “0” and “1”.

As used herein, the term “qudit” generally refers to a multi-level quantum system or to a qubit.

As used herein, the term “physical qubit” generally refers to a physical implementation of a qubit.

As used herein, the term “physical qudit” generally refers to a physical implementation of a qudit.

As used herein, the term “logical qubit” generally refers to the abstract concept of a qubit, which may be realized by one or more physical qubits. It is to be understood that the logical qubits form an abstract Hilbert space used for quantum information processing (e.g. quantum computation); that the logical qubits are encoded using various degrees of freedom of the physical qubits; that the physical Hilbert space associated to the physical qubits is often of much higher dimension than the logical Hilbert space and therefore allows the physical qubits to protect the logical qubits against various sources of error.

As used herein, the term “logical qudit” generally refers to the abstract concept of a qudit, which may be realized by one or more physical qudits.

A collection of n qubits has its “quantum state” in the Hilbert space which is the tensor product of the Hilbert spaces of the individual qubits.

A collection of n qudits has its “quantum state” in the Hilbert space which is the tensor product of the Hilbert spaces of the individual qudits.

As used herein, the term “quantum gate” generally refers to a unitary operation performed on the collective quantum state of one or more qubits or qudits.

As used herein, the term “Pauli gate” generally refers to one of the Pauli quantum logic gates X, Y or Z.

As used herein, the term “error” generally refers to any undesirable transformation of the qubits or qudits, whose cause may include but is not limited to natural qubit or qudit decoherence, thermal interactions, or interaction with a control apparatus.

As used herein, the term “error rate” when applied to any event (such as a quantum gate, qubit or qudit preparation, qubit or qudit measurement, qubit or qudit wait time, or error correction gadget) refers to the probability that the event contains errors.

As used herein, the term “noise channel” generally refers to a mathematical model of the errors afflicting a desired circuit when physically implemented. Noise channels are often expressed as CPTP (completely-positive trace-preserving) maps, and often have error rates for various components as parameters.

As used herein, the term “quantum error correcting code” generally refers to a procedure for constructing a working logical qubit or qudit with low error rate from many physical qubits or qudits with high error rates.

As used herein, the term “data qubit” generally refers to one of the physical qubits used to encode quantum information.

As used herein, the term “data qudit” generally refers to one of the physical qudits used to encode quantum information.

As used herein, the term “code space” refers to a Hilbert subspace of the Hilbert space of the physical qubits. Given a wavefunction in the code space, the state of the logical qubits may be extracted.

As used herein, the term “data qubit error rate” refers to the probability of errors in each data qubit in a given unit of time.

As used herein, the term “data qudit error rate” refers to the probability of errors in each data qudit in a given unit of time.

As used herein, the term “code distance” generally refers to the minimum number of errors required to switch from one encoded state to another. In some embodiments, it is translated to the number of qubits or qudits along one side of the patch of data qubits or qudits used to encode a single logical qubit or qudit. It is equal to the minimum possible number of data qubit or qudit errors which can lead to an error in the logical qubit or qudit state.

As used herein, the term “syndrome qubit” generally refers to one of the physical qubits, used to detect errors.

As used herein, the term “syndrome qudit” generally refers to one of the physical qudits, used to detect errors.

As used herein, the term “syndrome” generally refers to the combined readouts of (possibly many) measurements from the syndrome qudits or qubits.

As used herein, the term “recovery operation” generally refers to a proposed set of gates to apply to the data qubits or data qudits.

As used herein, the term “decoder for a quantum error correcting code” generally refers to a method and system which take as input a number of syndromes and yields as output a recovery operation which is intended to restore the state of the logical qubit or the logical qudit before the error occurred.

As used herein, the term “round of error correction” generally refers to one end-to-end pass through the quantum error correcting code.

As used herein, the term “logical error rate” generally refers to the probability of occurrence of a logical error in the logical qubit or qudit in a given unit of time. In one embodiment, it is calculated by finding the frequency with which one round of the entire error correction scheme results in an error in the logical qubit.

As used herein, the term “neural network” generally refers to a computational graph with some subset of nodes designated as “inputs” having only outgoing edges, some subset of nodes designated as “outputs” having only incoming edges; for each node with parameters, the gradient of its associated function with respect to its parameters is itself an easily computable function.

As used herein, the term “feedforward neural network” generally refers to a neural network with no cycles and wherein every path from an input to an output has the same length.

As used herein, the term “input layer” generally refers to the set of input nodes.

As used herein, the term “layer” generally refers to the set of nodes of a fixed equal distance from the input layer.

As used herein, the term “input vector” generally refers to a vector to enter into the input node or nodes.

As used herein, the term “output vector” generally refers to a vector to enter into the output node or nodes.

As used herein, the term “training data” generally refers to a set of (x, y) pairs, where x is an input data point and y is an output data point.

As used herein, the term “syndrome extraction circuit” generally refers to a circuit which is used to entangle one or more syndrome qubits or qudits with the data qubits or qudits and prepare the syndrome qubits or qudits in a state which can be (a) measured without collapsing the logical state of the quantum computation being protected and (b) results of these measurements can used to extract information about the errors afflicting the physical qubits or qudits.

In the following detailed description, reference is made to the accompanying figures in which similar symbols typically identify similar components, unless context dictates otherwise.

### Multi-Level Quantum System

A multi-level quantum system may be structured in a way which operates based on quantum mechanical processes such as superposition and entanglement of quantum states. A multi-level system can include a system with two or more energy states of an artificial or natural atom, for example, the ground (|0>) and first excited state (|1>) of a superconducting artificial atom. Such a multi-level system can have 0, 1, . . . , n energy states. A multi-level quantum system may be referred to as a “qudit” and multiple qudits may be used to implement a quantum computing system. A qudit may be thought of as one of n quantum states 0, 1, . . . , n−1 or a superposition of any of the n states. Specific subcategories of qudits exist, including a system consisting of only two energy states, the ground (|0>) and first excited state (|1>). These two-state systems are referred to as “qubits”. Each qubit can be placed in one of these two states. However, due to the nature of multi-level quantum systems, they can also be placed in a superposition of these two states. Entangled qubit or qudit devices can perform computational tasks.

### Quantum Error Correcting Code

A quantum error correcting code (QECC) can be implemented by constructing one or more working logical qudits with a relatively low error rate from several physical data qudits with a relatively higher error rate. A QECC may be characterized by several parameters, including, for example, the number of data qudits (denoted by n), the number of logical qudits (denoted by k), and the number of errors which may occur to a code state and still be corrected (called the code distance and denoted by d).

In some implementations, QECCs may be constructed as a natural extension of the classical error correcting codes (ECCs), which can encode one or more logical bits using many low-fidelity bits by correcting bit-flip errors.

A distinguished class of QECCs is given by stabilizer codes. The general stabilizer formalism is as follows. An abelian subgroup K of the n-qudit Pauli group is chosen, this is called the stabilizer subgroup. A set of generators A_1, A_2, . . . , A_k is chosen for K. The code space is the space of states of the data qudits which are stabilized by A, i.e. eigenstates of eigenvalue+1. The code space therefore encodes n-k logical qudits. Simultaneously measuring each of the stabilizers A_1, A_2, . . . , A_k projects the data state to the code space. For details, see Gheorghiu, V.; “Standard Form of Qudit Stabilizer Groups” https://arxiv.org/abs/1101.1519 and Gottesman, D.; “An Introduction to Quantum Error Correction and Fault-Tolerant Quantum Computation” (2009), https://arxiv.org/abs/0904.2557 which are incorporated by reference as part of the specification of this patent document.

One of the embodiments of stabilizer codes are CSS codes. CSS codes are defined using the Calderbank-Shor-Steane (CSS) construction, which produces a single QECC from two nested linear ECCs, C′<C, with the same number of data bits. The logical qubit is encoded within the subquotient C/C′. The reason this construction produces a QECC is that (1) the ability to correct both Pauli X (bit-flip) errors and Pauli Z (phase-flip) errors enables full quantum error correction, and (2) application of the Hadamard gate flips a code to its dual, and interchanges X errors for Z errors. For CSS codes, each stabilizer generator is either of X-type or of Z-type. (For examples, see Chapter 10 of “Quantum Computation and Quantum Information” by M. Nielsen and I. Chuang (10th Anniversary Edition, ISBN 978-1-107-00217-3, Cambridge University Press, 2010, http://mmrc.amss.cas.cn/tlb/201702/W020170224608149940643.pdf) which is incorporated by reference as part of the specification of this patent document.

The full QEC procedure can be implemented as follows. At regular time intervals, syndrome extraction circuits comprising data qudits and syndrome qudits are executed. Such a syndrome extraction circuit operates a sequence of physical qudit gates and performs a “stabilizer measurement” to produce readouts from the syndrome qudits. This collection of readouts is referred to as a “syndrome”. This syndrome data provides incomplete information about the error which has occurred, and is sent to the classical decoder which infers the most likely error which caused that syndrome. The decoder returns a candidate recovery operation, which is then applied to the data qudits.

Various classical algorithms have been developed to perform efficient and accurate decoding, depending on the code used. Some examples and their implementation details can be found in “Triangular color codes on trivalent graphs with flag qubits” by C. Chamberland et. al., https://arxiv.org/pdf/1911.00355.pdf (2020); “Efficient color code decoders in d≥2 dimensions from toric code decoders” by Kubica and N. Delfosse, https://arxiv.org/pdf/1905.07393.pdf (2019); “Almost-linear time decoding algorithm for topological codes” by N. Delfosse, N. H. Nickerson, https://arxiv.org/pdf/1709.06218.pdf (2017). and “Fault-tolerant error correction with the gauge color code” by Brown et al. (2015) (https://arxiv.org/abs/1503.08217), which are incorporated by reference as part of the patent specification of this patent document.

In some implementations, such an algorithm may be performed on a special-purpose classical decoder which is external to the quantum processor. For example, the special-purpose decoder disclosed herein may operate at a sufficiently low cryogenic temperature and may be placed in the physical proximity of the quantum processor at a desired low cryogenic temperature enabling communication lag minimization. As a specific example, the special-purpose decoder may be placed at a suitable cryogenic temperature in the range of tens of mK to a several Kelvin such as 10 mK, 100 mK, 600 mK, 3K or 4K and the cryogenic temperature of the quantum processor is at tens of mK.

More details on quantum error correction techniques can be found in “Quantum Error Correction for Beginners” by Devitt, S. J.; Munro, W. J.; Nemoto K.; https://arxiv.org/pdf/0905.2794.pdf (2013) and Chapter 10 “Quantum error-correction” in the above cited 2010 book by Nielsen, M., Chuang, I.; http://mmcc.amss.cas.cn/lib/201702/W020170224608149940643.pdf, which are incorporated by reference as part of the patent specification of this patent document.

A topological error correcting code is a stabilizer code where the qudits obey a fixed physical layout, and the logical qudit space is identified with the second homology group of the surface containing the qudits. In this situation, each stabilizer generator corresponds to a two-dimensional face on the surface, referred to as a plaquette.

### Fault Tolerant Quantum Computation

A quantum computing device and its operations can be characterized by logical and physical components of the quantum device. The physical components of the device are the actual hardware which includes qubits, gates, etc. whereas the logical components represent logical functions of the device such as the logical qubits, gates, etc. and refer to the abstract information which is manipulated in the computation performed on the device. As previously mentioned, in various implementations, the construction of one logical qubit according to a QECC may use multiple physical qubits and physical gates.

Gate-model quantum computation involves not just logical qubits, but logical components such as qubit preparation, quantum gates, qubit measurement, and waiting (preserving the state of the qubit), which all act on the logical state. Any of these components may fail in operation, and may introduce errors into the physical state. In the circumstances, when the number of errors introduced is too large so that such errors in the physical state may no longer be corrected by the QECC, the logical state may be erroneous as well.

Fault tolerant quantum computation refers to a protocol which implements all of these components in a way which is resistant to errors, i.e., the logical outcome of the quantum computation can be made the same as if no failures occurred, provided that the number of errors introduced is not too large beyond the error correction capacity of the device. Some information on fault tolerant quantum computation can be found in “An Introduction to Quantum Error Correction and Fault-Tolerant Quantum Computation” by Gottesman, D.; https://arxiv.org/pdf/0904.2557.pdf (2009). Fault tolerance can be essential to useful quantum computing, and building a fault tolerant device is desirable in constructing a practical quantum computing system. To achieve fault tolerant quantum computation, an error correction gadget or module can be used to produce a single fault-tolerant logical qubit, and, based on this, fault tolerant gadgets or modules can be provided to correspond to the other components of a quantum circuit such as fault tolerant preparation, fault tolerant gates, etc. Multiple schemes for fault-tolerant quantum computation have been proposed, which use quantum error correcting codes in various ways. Constructing and using fault-tolerant gadgets in the case where each logical qubit is itself encoded in a QECC presents architectural challenges. Further details may be found in “A Game of Surface Codes: Large-Scale Quantum Computing with Lattice Surgery” by Litinski, D., https://arxiv.org/pdf/1808.02892.pdf (2019); “Surface code quantum computing by lattice surgery” by Horsman, C. et al, https://arxiv.org/pdf/1111.4022.pdf (2013); “Fault-tolerant quantum computing with color codes” by Landahl, A. J., Anderson, J. T., Rice, P. R., https://arxiv.org/pdf/1108.5738.pdf (2011); and “Surface codes: Towards practical large-scale quantum computation” by Fowler, A. et al, https://arxiv.org/ftp/arxiv/papers/1208/1208.0928.pdf (2012), which are incorporated by reference as part of the patent specification of this patent document.

### Fault Tolerant Error Correction

A suitable error correction gadget for implementing the disclosed technology can include syndrome extraction circuits implemented as part of the quantum processor and a decoder implemented as part of a classical processor. It is a consequence of the threshold theorem (see Gottesman, D.; arXiv:0904.2557 (2009) that if the error rate of the physical components syndrome extraction circuits is below a fixed threshold (determined empirically and varying based on the QECC used), and we have a perfect decoder, then the failure rate of the error correction gadget can be made arbitrarily small by increasing the code distance of the QECC. A perfect decoder is likely impossible in practice, and moreover the decoding problem becomes harder to solve as the code distance is increased. One way for implementing a practical decoder is to construct decoders based on neural networks for solving the decoding problem as described by some examples of such decoders in an article entitled: “Deep neural decoders for near term fault-tolerant experiments” by Chamberland, C., Ronagh, P., arXiv:1802.06441 (2018), https://arxiv.org/abs/1802.06441) which is incorporated by reference as part of the patent specification of this patent document.

### Recurrent Neural Network

One of the candidates for the function approximator of the decoder is a recurrent neural network. This neural network model may have an architecture which is simple enough to build, but yet complex enough to fit the training data and thereby accurately mimic a decoder. A recurrent neural network is a natural approach to handling time-sequenced nature of the syndrome measurements.

A recurrent neural network maintains an internal state vector, which is initialized as some pre-determined vector. A single recurrence step can be implemented by passing this internal state vector along with an input vector through a first feedforward neural network which yields a new internal state vector for the recurrent neural network. The extraction step is performed by passing the internal state vector through a second feedforward neural network which yields an output vector.

One full pass of inference using a data point containing N rounds of measurements on each syndrome qubit, includes N round of recurrence steps (each using one of the measurement sets) followed by a single extraction step.

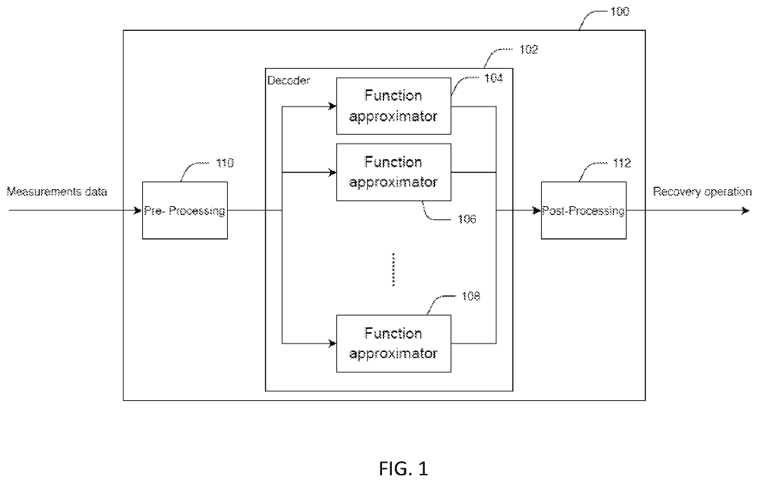

FIG. 1 shows an example of an embodiment of a cryogenic classical superconducting circuit 100 for implementing the decoder part of the error correction gadget or module based on the disclosed technology in this patent document. The cryogenic classical superconducting circuit 100 is operated at one or more cryogenic temperatures to maintain proper operating conditions for superconducting circuits inside. The cryogenic classical superconducting circuit 100 may include a decoder 102 of quantum error correcting codes. The decoder 102 of quantum error correcting codes includes one or more function approximator modules 104, 106, and 108. The decoder of quantum error correcting codes includes a plurality of nodes, a plurality of interconnects between nodes of the plurality of nodes for distributing pulses between the nodes, and a plurality of weights. The cryogenic classical superconducting circuit includes mixed-signal, digital and/or analogue Josephson junction superconducting electronics, which may include magnetic junctions and/or quantum phase slip devices. In operation, such a cryogenic classical superconducting circuit 100 is provided to interface with one or more syndrome qudits to receive the measurement data of the one or more syndrome qudits.

In one embodiment, the Josephson junction superconducting electronics includes single flux quantum logic. In another embodiment, the Josephson junction superconducting electronics includes adiabatic quantum flux parametron type circuits. In other embodiment, the Josephson junction superconducting electronics includes SQUIDs or Bi-SQUIDs. The Josephson junction superconducting electronics may be constructed based on one or more suitable digital and mixed-signal quantum flux circuits such as ERSFQ, eSFQ, AQFP, RQL, RSFQ, SFQuClass, nSQUID-based, or analog circuits using SQUIDs and Bi-SQUIDs.

The function approximator 104, 106, or 108 may be implemented in various configurations, such as function approximator examples disclosed herein. One example of such a function approximator can include a mapping from input vectors to output vectors, manifested as a logically computable function, and possibly having tunable parameters which determine the underlying mapping. By tuning the parameters through a process referred to as training described elsewhere herein, a function approximator can be fitted to a given training dataset of input-output pairs, thereby approximating the true function from which the training data is generated. Once trained, the function approximator mapping approximates the true function by matching its behavior on the training dataset.

In one embodiment, the function approximator includes a classical logical circuit that efficiently computes the correspondence between the syndromes and errors. In another embodiment, this classical logical circuit includes a table for mapping syndromes to errors. In another embodiment, the classical logical circuit can be implemented by using a hash function implementing or approximating this table.

In another embodiment, the classical logical circuit can be implemented based on a hardware-efficient combinatorial algorithm for computing the syndrome to error correspondences. In one embodiment such a combinatorial algorithm may include minimum-weight perfect matching (MWPM) as one or multiple of its subroutines as illustrated by examples in the 2012 article entitled “Topological code Autotune” by A. G. Fowler, et al. (https://arxiv.org/abs/1202.6111] which is incorporated by reference as part of the patent specification of this patent document. In another embodiment, the combinatorial algorithm may include union-finding (UF) as a subroutine as illustrated by examples in the article entitled “Almost-linear time decoding algorithm for topological codes” by N. Delfosse and N. H. Nickerson at https://arxiv.org/abs/1709.06218 (2017) which is incorporated by reference as part of the patent specification of this patent document.

In one embodiment, the function approximator can be implemented by including a neural network as illustrated by examples in the 2013 book entitled “Neural Networks and Deep Learning” by Nielsen, M., http://neuralnetworksanddeeplearning.com/and a book entitled “An Introduction to Statistical Learning: with Applications in R” by James, G.; Witten D.; Hastie T.; Tibshirani R, https://link.springer.com/book/10.1007/978-1-4614-7138-7) which are incorporated by reference as part of the patent specification of this patent document.

The neural network may be of various types including but not limited to a deep neural network. In certain embodiments the deep neural network may include convolutional, recurrent, or feedforward units.

The neural network may have nodes with activation functions such as rectified linear or sigmoid functions.

In another embodiment the neural network may be based on a probabilistic graphical model. In one or more embodiments the probabilistic graphical model may include a Hopfield neural network, or a Boltzmann machine.

In another embodiment, the function approximator includes at least one linear function. In yet another embodiment, the function approximator includes at least one of a regression unit, a classifier, a decision tree, and a random forest. More details on examples of function approximators can be found the above referenced book entitled “An Introduction to Statistical Learning: with Applications in R.”. It will be appreciated that if the decoder has weights, such weights are representative of the at least one function approximator parameters. In the embodiment wherein the function approximator is a neural network, the tunable parameters may include the coefficients of the linear matrices between the layers of the neural network. It will be further appreciated that a function approximator may itself contain multiple function approximators as components within itself.

Still referring to FIG. 1, the cryogenic classical superconducting circuit 100 may include the pre-processing unit 110 before the decoder 102 to transform the measurements data from the syndrome qudits or qubits into the input suitable for the function approximator 104, 106, or 108 for processing. The cryogenic classical superconducting circuit 100 may further include the post-processing unit 112 to transform the output from the function approximator 104, 106, or 108 into the recovery operation.

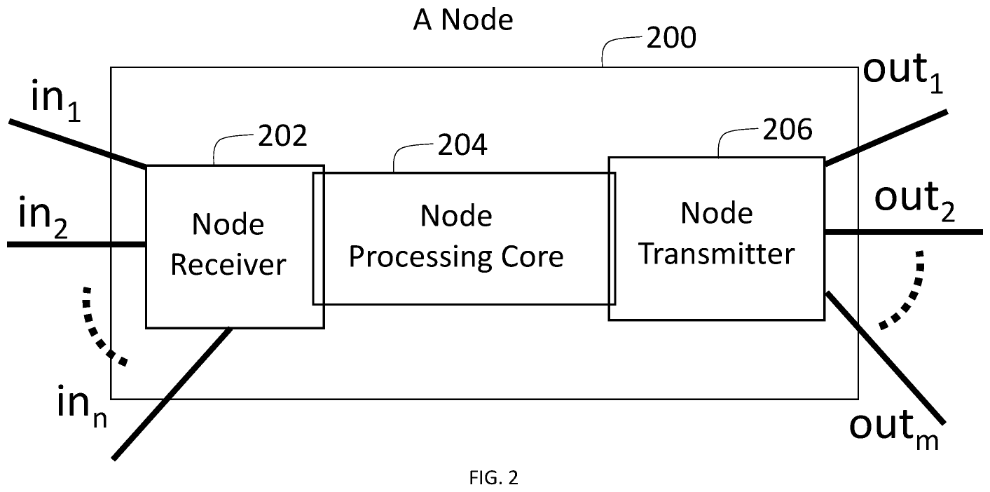

FIG. 2 shows a diagram of an example of a node of a function approximator of a decoder disclosed herein such as the decoder example in FIG. 1. Such a node can be a node in a neural network in some implementations.

Each node 200 in the decoder includes a receiver section 202 that receives one or more input signals (in₁, in₂, . . . , inₙ) from one or more other nodes, a processing core 204 that processes the input signals, and a transmitter section 206 that, based on the results of the processing by the processing core 204, creates outputs for nodes in other layers, or outputs representative of the function approximator results. In the embodiment wherein the function approximator is a deep neural network the receiver section 202 receives input signals from nodes in a previous layer or from a syndrome extraction circuit.

In FIG. 2, each node 200 can be considered as three overlapping sections 202 (receiver), 204 (processing core) and 206 (transmitter) with different functionality. The receiver section 202 collects all the signal generated from nodes in preceding layers or the syndrome extraction circuit as part of the cryogenic classical superconducting circuit. Each input to a node in a layer of the inputs from nodes in previous layer may be scaled by a corresponding weight. In one or more embodiments, all the weighted inputs from the nodes in the previous layer are summed up together in the receiver and fed to the processing core. The processing core 204 receives the signal from the receiver 202 and applies the activation on it. The activation is implemented by an activation circuit which maps an input signal to an output signal. This mapping could be of different forms, but in general is mostly nonlinear. In implementations, certain nonlinearity is introduced into an activation circuit to the flow of the signal. Different forms of nonlinearity can be used such as ReLU (rectified linear activation function unit), Sigmoid, and others. In general, in the activation circuit the input which is in some cases the summation of all the signals from previous nodes weighted by the corresponding weights is mapped to an output signal which depends on the details of the activation circuit. This mapping in most cases is nonlinear in nature. Depending on the desired functionality the activation circuit can be as simple as a threshold activated circuit, where only an output is produced if the input is above a threshold. In other implementations, the activation circuit could implement a more complex mapping like ReLU or other functions.

In a neural network implementation, the nodes in the input layer interfacing with syndrome qudits have one input each to the node receiver 202 and this single input carries the digital information originating from the syndrome measurement. The single weights for all the nodes in the input layer are the same and could be assumed to be unity in some implementations. The processing core 204 converts this digital signal arriving in the node receiver 202 to a pulse that is fed to inner layers of the neural network. Therefore, the nodes in the first layer each receive a single digital pulse and convert it to a pulse that is fed to multiple of nodes in following layers. Examples of this converter can be based on the SFQ to DC converter disclosed by V. K. Kaplunenko, V. P. Koshelets, K. K. Likharev, V. V. Migulin, O. A. Mukhanov, G. A. Ovsyannikov, V. K. Semenov, I. L. Serpuchenko, and A. N. Vystavkin in “Experimental Study of the RSFQ Logic Circuits” in Extended Abstracts of International Superconductive Electronics Conference (ISEC '87), Tokyo, pp. 127-130 (August 1987), which is incorporated by reference as part of the disclosure of this patent document. In SFQ to DC converters, fast SFQ pulses are converted to slow varying or fixed amplitude voltage pulses. The slow varying voltage pulses are more convenient to be processed in the neural network.

In implementing the disclosed technology, a decoder may be designed to implement different types of activation circuits for different nodes of a layer or different layers. For example, the activation used in the nodes in hidden layers could be ReLU and the activation circuit on the last layer could be a threshold detector circuit. In general, different activation functions using different numbers of components, topology and working conditions may be implemented.

An example of the activation function is ReLU. The output of the processing core 204 is fed to transmitter 206 to be broadcasted to nodes in the next layer. The transmitter 206 is designed such that the signal is strong enough to be sent to next layer. The output of the transmitter 206 could be a single output or multiple outputs depending on the interconnect in the network. For example, if the signal is fed serially to the next layer the output is a single line or alternatively it can be parallel outputs in case of parallel feed to the next layer. In the transmitter section an amplifier could be designed to strengthen the signal if necessary.

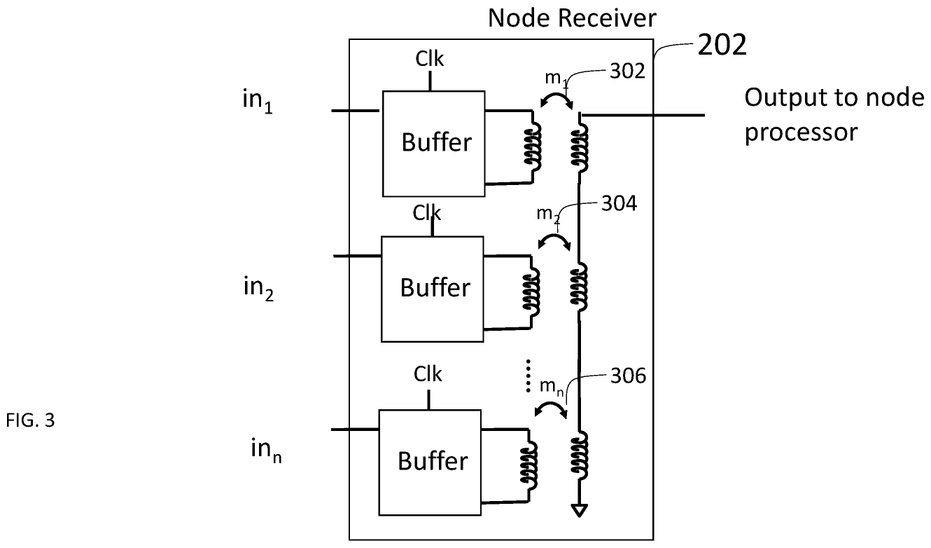

Now referring to FIG. 3 there is shown a diagram of an example of an embodiment of a node receiver section 202 for implementing the node in FIG. 2. This particular example of the receiver section receives at least one pulse comprising a magnetic flux, current, or voltage as an input signal. The receiver section in this example includes input buffers storing input signals, respectively and signal coupling circuits for applying signal weights to the received input signals, respectively.

In operation, the receiver section 202 is structured and operated to apply a corresponding weight on each individual input signal it receives. In one embodiment the weights of the decoder of quantum error correcting codes are applied using a fixed signal coupling which may be achieved by a magnetic coupling circuit as illustrated, a capacitive coupling circuit or a resistive coupling circuit. In one embodiment a fixed magnetic coupling circuit includes a transformer 302, 304, or 306 each formed by a pair of magnetically coupled inductors. In this embodiment, the input signals (in₁, in₂, . . . , inₙ) are applied with their corresponding weights by magnetic couplings via different transformers 302, 304, and 306. In such an embodiment, different coupling strengths are used for different input pulses in a transformer to represent corresponding weights and the fixed magnetic coupling is proportional to the corresponding weight.

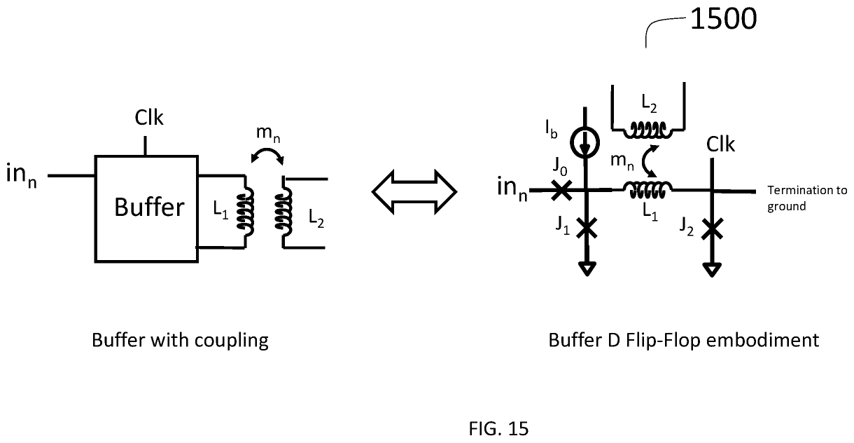

Now referring to FIG. 15 there is shown an embodiment of an example of an input buffer with coupling and a D flip-flop buffer function for storing an input signal. Such input buffers are added to store and synchronize the weighted couplings of the different input signals originated from the previous nodes. One function of the buffers is to store the input signals and to use their respective clock signals (CLKs) to control the timing of the input signals to be applied with the weights so that all the weighted couplings occur at the same time.

In one embodiment, a buffer is a D flip-flop buffer 1500 as shown by the circuit shown on the right hand side in FIG. 15, which includes Josephson junctions J₀, J₁, and J₂, a transformer formed by inductors L₁ and L₂, and a current source I_{b}. An input signal that is received by the junctions J₀ switches the junction J₁ and creates a flux which is stored in the inductor L₁. The stored flux consequently couples to L₂ with an associated weight mₙ. After all input signals have arrived at their corresponding input buffers, a clock signal CLK is applied to the Josephson junction J₂ in each buffer to reset the D flop-flop by switching the Josephson junction J₂ and removing the flux, readying it for the next round of pulses.

It will be appreciated that the resistive coupling may include a voltage divider. Different coupling strengths may be used for different input pulses in the voltage divider to represent the weights of the plurality of weights. Fixed resistive coupling is proportional to the weight.

In another embodiment the weights of the decoder of quantum error correcting codes are applied using a variable coupling. The variable coupling may be a magnetic coupling, a capacitive coupling or a galvanic coupling.

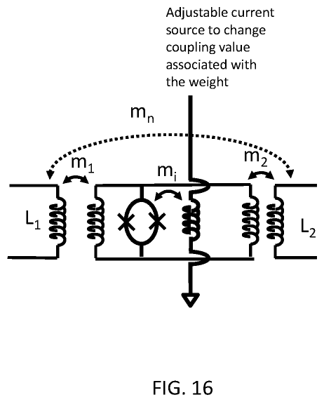

In one embodiment, the variable magnetic coupling is implemented using an interposed SQUID inside a two-stage transformer as shown in FIG. 16. By changing the adjustable current, the amount of the flux deposited to the SQUID changes. This will make the effective coupling, mₙ, between L₁ and L₂, a variable function depending on the adjustable current.

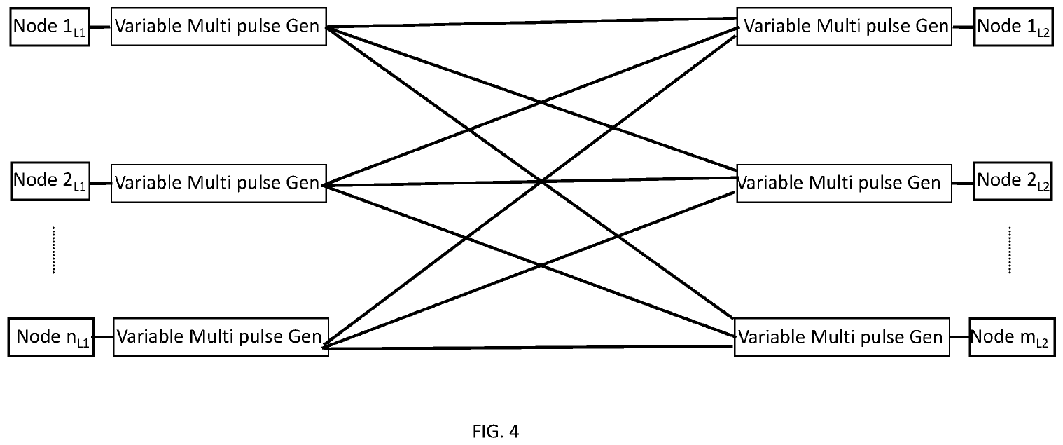

Now referring to FIG. 4, there is shown another embodiment of a variable weight implementation. The weights are encoded in the number of generated SFQ pulses. The variable weight is implemented by varying the number of generated SFQ pulses proportionally to the corresponding weights. Still in the variable coupling embodiment wherein a multiple number of SFQ pulses is generated, the Josephson junction superconducting electronics may include a SQUID. Herein, the number of generated pulses is varied by changing the bias current or the critical current of the SQUID. In this embodiment, the variable multi pulse generator may be implemented in either transmitting node, receiving node or in both transmitting and receiving nodes.

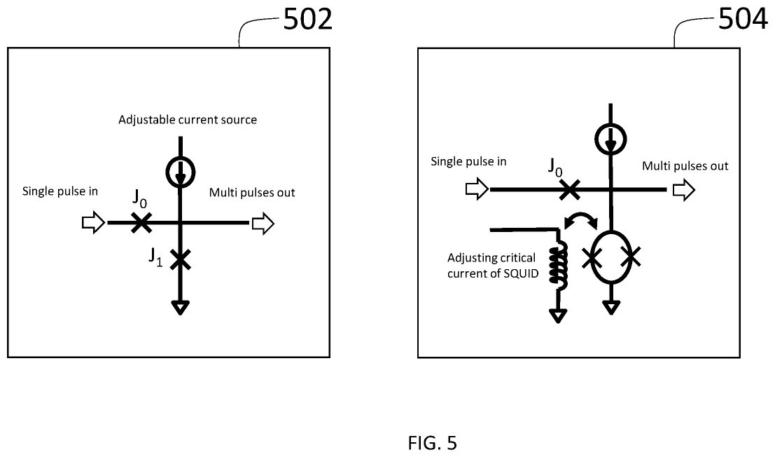

Now referring to FIG. 5, there are shown two embodiments 502 and 504 of a variable multi pulse generator based on an adjustable current source. The generated variable multiple pulses are SFQ pulses. In the multi pulse generator 502 with two Josephson junctions J₀ and J₁, the number of output pulses is controlled by using an adjustable current source. In the multi pulse generator 504 with a Josephson junction J₀, a SQUID and a current source, the number of output pulses is controlled by adjusting the critical current of the SQUID with an external magnetic field from an inductor that is magnetically coupled to the SQUID.

It will be appreciated that the variable weight implementation enables programmable weights, which can be adjusted as a result of training.

Now referring back to FIG. 2, the processing core 204 implements an activation function for the node 200. Different activation functions such as sigmoid and rectified linear unit (ReLU) may be implemented using different values of the circuit parameters including the shunt of junctions and different number of Josephson junctions as well as different topologies.

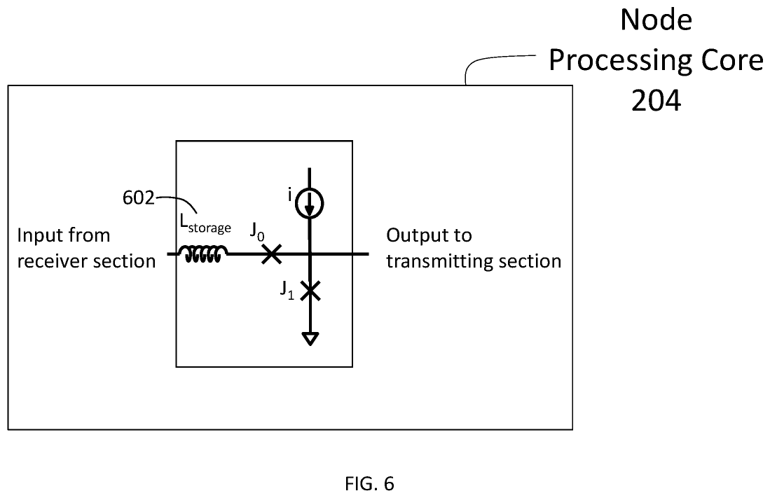

Now referring to FIG. 6, there is shown an embodiment of a node processing core 204 with an activation function based on a threshold. The activation circuit here works like a soft binary step function: if the input is above some threshold the output is the digital high, and if the input is below some threshold the output is the digital low. In the decoder, based on the value of input, the output of each node is a digital pulse that is fed to the error correction circuit. In one embodiment, a simple threshold comparator is used to implement a sigmoid function. In this embodiment, the processing core 204 includes two Josephson junctions J₀ and J₁ coupled to a current source to generate output pulses based on a threshold. Specifically, in this embodiment, if the combined amplitude of the input pulse and the bias current from the current source exceeds the critical current of the Josephson junction J₁, the Josephson junction J₁ switches and thus creates one pulse to the output.

In some embodiments the processing core 204 includes at least one superconducting storage loop 602 (inductor L_{storage} coupled to the input) for storing the magnetic flux. The storage loop 602 receives the signal from the receiver section 202 and based on the stored value outputs relevant signals.

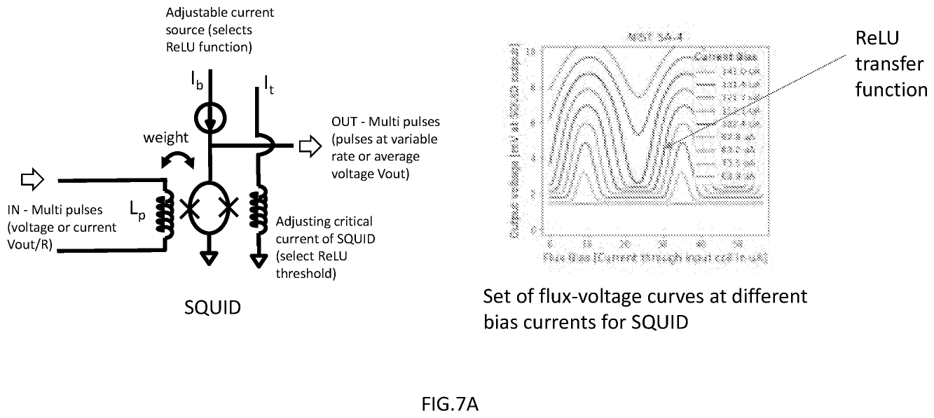

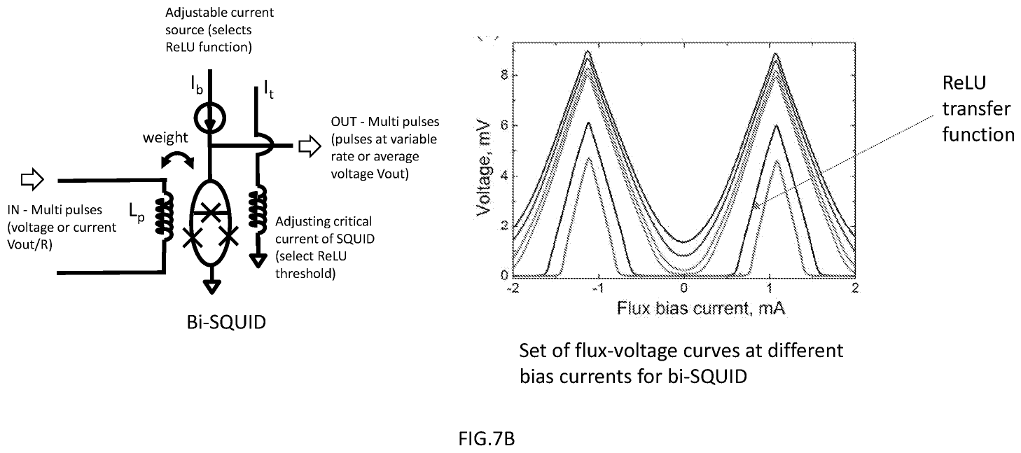

Now referring to FIG. 7A, there is shown an embodiment of a node processing core 204 in FIG. 2 with a rectified linear unit (ReLU) activation function using SQUID and an adjustable bias current source I_{b} of the SQUID. The transfer function of the SQUID approximates rectified linear unit (ReLU) function to the first degree. Here Lp represents the effective inductance of an input inductor in the receiver section and another inductor is coupled to the SQUID to carry an adjustable critical current Iₜ where the signal comes from and enters the processing core of the node through magnetic coupling. The adjustable bias current source I_{b} determines the functionality of the rectified linear unit (ReLU) function and the adjustable critical current Iₜ is used to determine the threshold for rectified linear unit (ReLU). If the input is smaller than a predefined threshold, no output is created; whereas, when the input signal exceeds the threshold set by Iₜ, depending on the strength of the signal, a variable number of SFQ pulses is generated. The number of output pulses per unit time (pulse rate or average output dc voltage) is determined by the rectified linear unit (ReLU) function. By adjusting the two currents I_{b} and Iₜ the working curve on the transfer function may be chosen.

Now referring to FIG. 7B, there is shown another embodiment of a node processing core with a rectified linear unit (ReLU) activation function using a Bi-SQUID to replace the SQUID in FIG. 7A to achieve highly linear flux-to-voltage characteristics. The functionality of the Bi-SQUID is similar to a SQUID with a difference that it may approximate a rectified linear unit (ReLU) function better. The transfer function of the Bi-SQUID shows a linear region that may be exploited for the linear section of the rectified linear unit (ReLU) function. The functionality of the circuit is similar to above SQUID version. Here, Lp represents the effective inductance in the receiver section where the signal comes from and enters the processing core of the node through magnetic coupling. The adjustable current source I_{b} determines the functionality of the rectified linear unit (ReLU) function and the adjustable critical current Iₜ is used to determine the threshold for rectified linear unit (ReLU). If the input is smaller than a predefined threshold, no output is created; whereas, when the input signal exceeds the threshold set by Iₜ, depending on the strength of the signal, a variable number of SFQ pulses is generated. The number of output pulses per unit time (pulse rate or average output dc voltage) is determined by the rectified linear unit (ReLU) function. By adjusting the two currents I_{b} and Iₜ the working curve on the transfer function may be chosen.

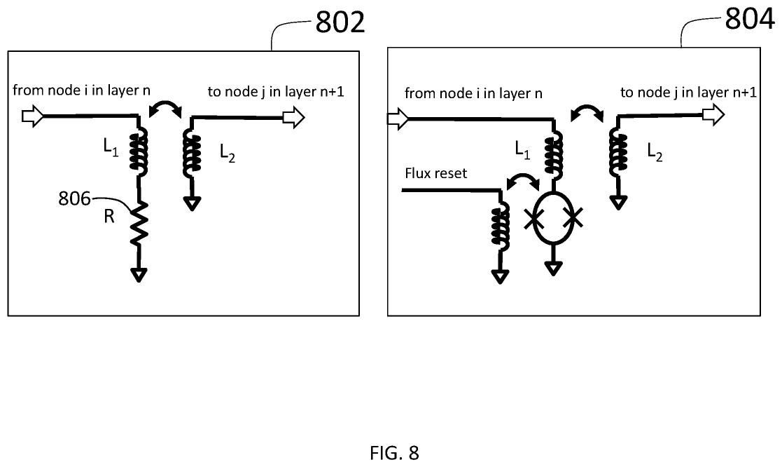

Now referring to FIG. 8, two embodiments of clearing the stored flux and resetting the circuit for the node processing core 204 are shown. Emptying the magnetic flux stored in storage loops resets the circuits and readies the node for the next input. In the embodiment 802 the magnetic flux is cleared using a loading resistor 806 with matching impedance where the stored flux will decay with the time constant L1/R where L1 is the total inductance in series with the resistor. In the other embodiment 804, the magnetic flux is cleared by using a SQUID with external flux control. By applying the external flux reset signal, the critical current of the SQUID is reduced which can drive the SQUID into normal state. In the normal state the stored flux will decay and readies the circuit for next round of decoding pulses.

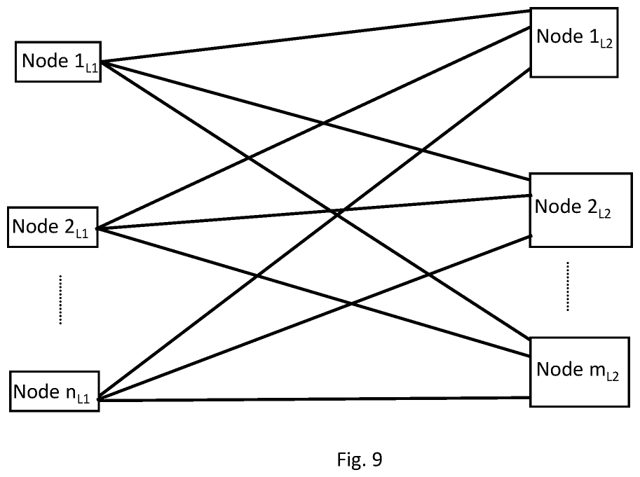

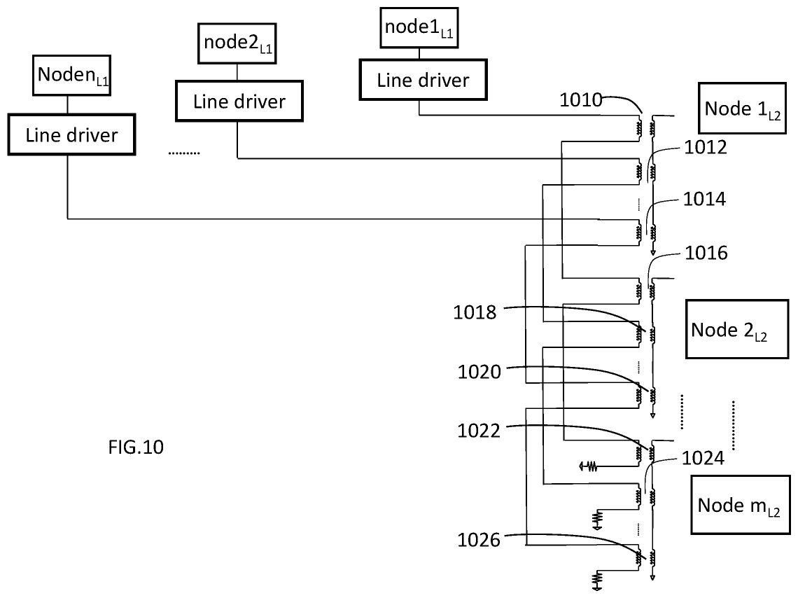

Now referring back to FIG. 2, the transmitter section 206 is responsible to connect the output of the node to receiver sections of nodes in the next layer or to output representative of the function approximator results. Various connection schemes may be implemented such as the examples in FIGS. 9 and 10. In one embodiment, the interconnections are direct one-to-one interconnections. In another embodiment the interconnections are implemented using a bus and different methods of parallelization and serialization to reduce the number of interconnects. An example of a fully serial interconnect is shown in an example in FIG. 10, in which a single line is coupled with multiple inductors that magnetically couple one node in one layer to inductors implemented in nodes in the next adjacent layer. An example of a direct one-to-one interconnect between nodes of two adjacent layers is shown in FIG. 9, where the output of each node in one layer may be distributed to different nodes in the next layer using various methods. In one embodiment of direct one-to-one connection, the output of each node is distributed using a tree of SFQ pulse splitters to create enough pulse for all the receiving modes. Splitters create identical copies of the input SFQ signal. The binary splitter which creates two output for every input is the most commonly used splitter. In the fully serial interconnect, the output current pulse couples to all receiver nodes and terminates to ground via resistor.

In one embodiment, the Josephson Transmission Lines (JTLs) or Passive Transmission Lines (PTLs) are used for transfer of the SFQ signals between nodes. JTLs use active Josephson junction elements for transfer of SFQ pulses. PTLs use passive microwave lines for transfer of the SFQ or current or voltage signals. In another embodiment, the pulse signal can be transduced to optics and back to electrical signals for interconnects between nodes. Diodes or other low energy photon generation techniques may be used to transduce an electric pulse to a photonic pulse. Superconducting Nanowire Single Photon Detectors (SNSPDs) or other low energy photon detectors may be used to transduce a photonic pulse to an electric pulse. In the embodiment with a photon interconnect, a low loss optical waveguide is used for the propagation of light where photon source and detectors are coupled efficiently to the photonic waveguide.

Various interconnection schemes may be implemented. Now referring to FIG. 10, there is shown an embodiment of interconnection scheme. In this embodiment, each transmitting node includes a driver for all the receiving nodes in a fully serial fashion using a single PTL line that is coupled to different nodes in the next layer (e.g., magnetic coupling via inductors as shown). Each receiving node couples to this line using its coupler (fixed or variable). Further each receiving node couples to all such lines from all transmitting nodes. The multiple received signals from different transmitting nodes are summed up at each receiving node. The connections 1010-1026 may be of various types. In one embodiment the connections 1010-1026 are electrical, such as an SFQ splitter. In another embodiment, the connections 1010-1026 are magnetic couplings using transformers. In yet another embodiment, the connections 1010-1026 include capacitive coupling.

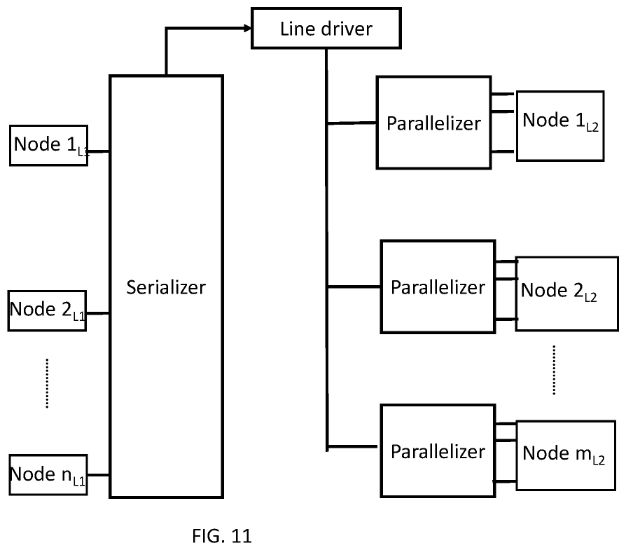

Now referring to FIG. 11, there is shown an embodiment of connectivity between nodes in two consecutive layers using parallelizers and serializers to reduce the number of interconnect wires. It will be appreciated that a combination of direct interconnect between nodes, serialization and parallelization may be used. The serializer is a serial-to-parallel converter circuit that serially reads out the output from each node in the transmitting nodes that signals originate. The data output of the serializer is then transmitted serially to the receiving nodes. At the receiving nodes, the information is parallelized using a serial-to-parallel converter that will be fed to the corresponding input with associated weighted coupling. The parallelzer is a parallel-to-serial converter.

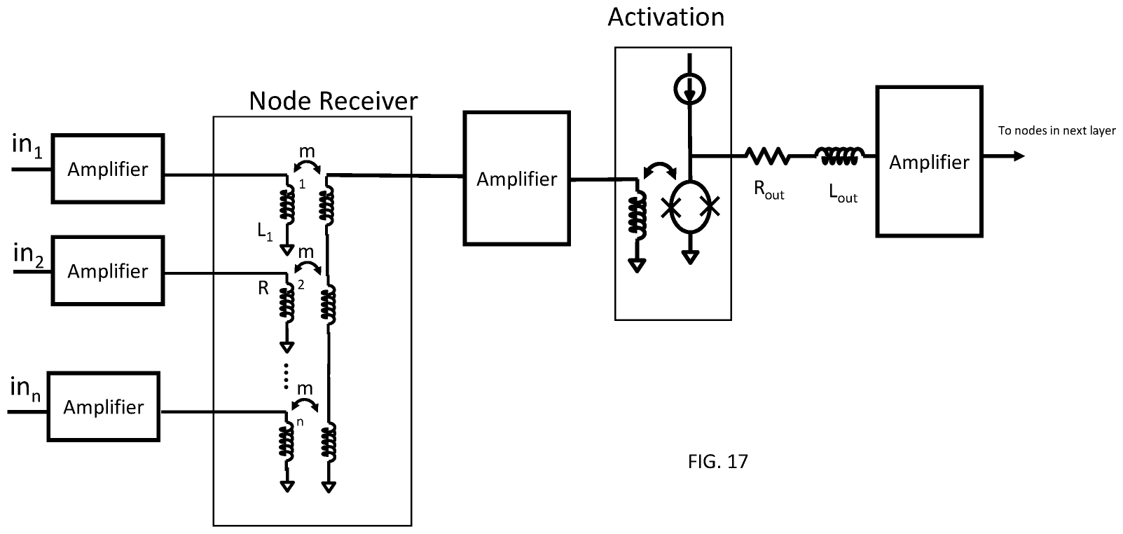

It will be appreciated that the signal may need to be amplified at different stages of the decoder. For example, in one embodiment, the signal of each node after the activation function may be amplified using amplifiers. In one or more embodiments, amplifiers may be implemented by using a plurality of Josephson junctions such as SQUIDs or biSQUIDs. FIG. 17 shows an example of an embodiment of amplifiers at various locations for a node: amplifiers placed at the input side of the node receiver 202 in FIG. 2, amplifiers in the node processing core 204 and the node transmitter 206 in FIG. 2. The amplifiers may be of various types. Each amplifier may be of a single or multiple stages.

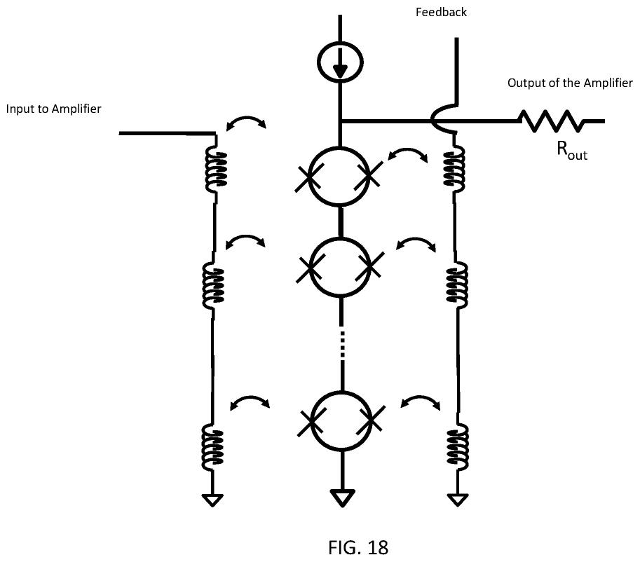

An embodiment of an amplifier with multi SQUIDs in series is shown in FIG. 18. Each SQUID in this example in FIG. 18 may be replaced with biSQUIDs or other suitable SQUID variations. A feedback mechanism, as illustrated by an example of a feedback circuit of a series of inductors coupled to the SQUIDS in FIG. 18, may be designed to change the linearity, dynamic range and/or other characteristics of the amplifier.

It will be appreciated that different modes of operation may be envisioned for different nodes and different sections thereof, i.e., analog, digital, and hybrid analog-digital designs. In one or more embodiments, wherein the nodes are organized in layers the nodes in the inner layer work in analog mode whereas the receiver section of the nodes in the first (input) layer and the transmitter section of the nodes in the last (output) layer work in digital mode. In particular, the receiver section 202 of the nodes in the input layer receives a digital signal and convert it to analog signal to be used in internal layers. The nodes in the output layer receive analog signals and create and transmit a digital signal as the output of the decoder. In one or more alternative embodiments, the nodes in the inner layer work in digital mode or an analog-digital hybrid mode. It will be appreciated that the decoder may be of various types such as the decoder 102 described elsewhere herein with respect to FIG. 1. In one or more embodiments, the output of the decoder is fed to the post-processing unit 112 to transform the output from the function approximator into the recovery operation.

It will be appreciated that the innerconnect between nodes may be analog or digital (i.e. patterns of SFQ signals). In one or more embodiments, the signal between nodes is converted to digital and then digitally sent between nodes. In other embodiments, the signal is analog voltage or current signal. In an alternative embodiment a hybrid combination may be envisioned. The information communicated between nodes may be encoded in number of SFQ pulses (digital), or may be encoded in the shape of pulses of different amplitude and length (analog).

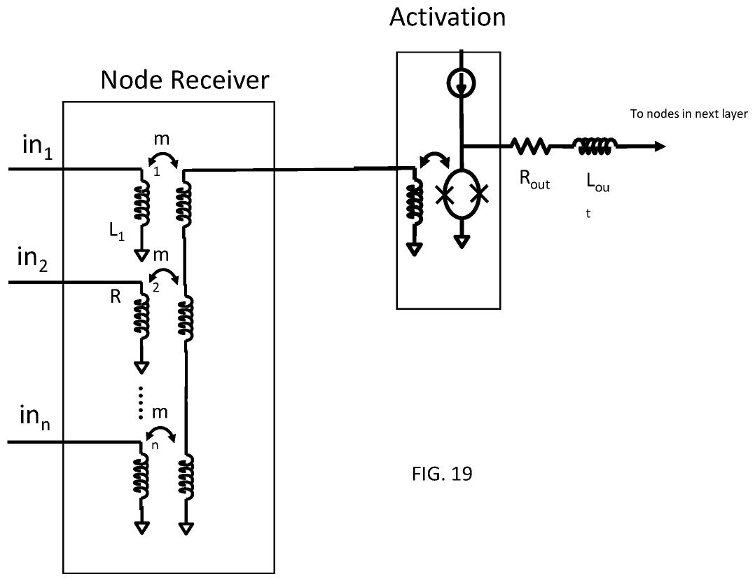

In the analog embodiment shown in FIG. 19, the input from the nodes in previous layers add up with different weights and coupled magnetically to an activation function circuit which may be a SQUID, biSQUID or a variation of that. The activation function circuit is designed such that the voltage is modulated by the flux created in the node receiver section. This voltage acting on the output resistor Rout creates an output current that may be fed to the nodes in the next layer.

The decoder system may be operated synchronously and asynchronously depending on the design of the system being analog, digital or hybrid.

In one or more embodiments, the signals propagate among nodes and at each node the signal is processed with different weights and then passes through activation function and the resulting signal also propagates to the next layer asynchronously. The synchronous or asynchronous operation may be used for different components. For example, the receiver sections of the nodes in the input layer that receive the digital signal and the transmitter sections of the nodes in the output layer that generate a digital signal may be operated synchronously whereas the nodes in the inner layers may be operating asynchronously.

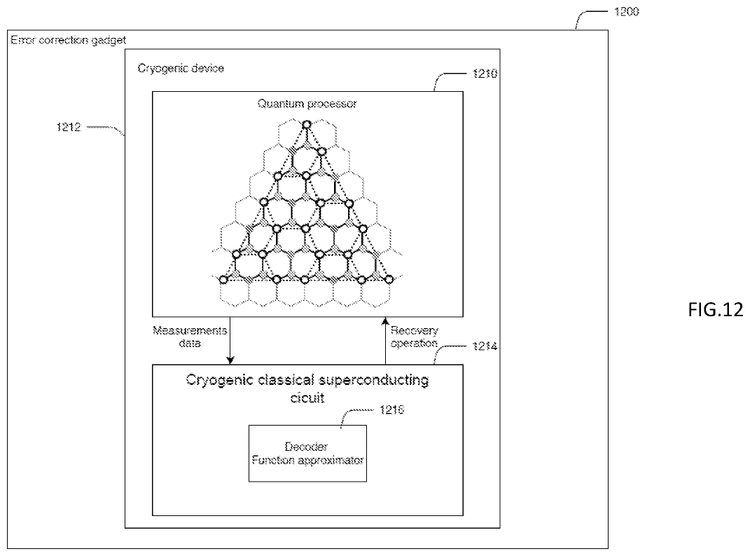

Now referring to FIG. 12, there is shown an embodiment of a quantum correction gadget or module 1200. The quantum correction gadget 1200 may include one or more syndrome extraction circuits that are designed for performing quantum error correction operations. The quantum processor 1210 also includes physical qubits or qudits for performing quantum computation operations for which the quantum error correction operations are provided. The quantum correction gadget 1200 further includes a separate cryogenic classical superconducting circuit 1214 that contains the decoder as shown in FIG. 1.

The quantum processor 1210 may be of various types. In some implementations, such a quantum processor uses the nature of entangled qudit or qubit devices to perform computational tasks. In the particular realms where quantum mechanics operates, particles of matter can exist in multiple states simultaneously, known as a superposition of states. Two or more qudits or qubits existing in a superposition of states can be entangled together. In the embodiment wherein the qudits include qubits each with two quantum states 0 and 1, entanglement means that qubits in a superposition can be correlated with each other in a non-classical way; that is, the state of one (whether it is a 1 or a 0 or both) can depend on the state of another, and that there is more information that can be ascertained about the two qubits when they are entangled than when they are treated individually. A system of two or more entangled qudits may be manipulated via quantum interference as part of quantum processing. Where binary computing is limited to using just the on and off states (equivalent to 1 and 0 in binary code), a quantum processor harnesses these quantum states of matter to output signals that are usable in data computing. The quantum processor 1210 may include a plurality of qudits comprising at least one data qudit and at least one syndrome qudit representative of an error correcting code. The plurality of qudits includes an error correcting code. The error correcting code may be of different types such as any type described herein. In one embodiment, the error correcting code includes a topological error correcting code such as a toric code, a surface code, a rotated surface code, a colour code, or a triangular colour code.

In FIG. 12, qudit readout circuits are provided and coupled to the quantum processor 1210 to interact with qudits to perform measurements on the qudits to provide the measurements data. Such qudit readout circuits may be implemented in various configurations, including readout circuits disclosed in U.S. Pat. No. 9,692,423 entitled “System and method for circuit quantum electrodynamics measurement” by inventors McDermott et al. https://patents.google.com/patent/US9692423B2/en?og=9692423 which is incorporated by reference as part of the specification of this patent document.

In connection with the operations of the quantum correction gadget 1200, the part of the qudit readout circuits that are coupled to interact with syndrome qudits within the quantum processor 1210 are used to perform measurements on the syndrome qudits without directly performing measurements on data qubits to provide the measurements data for the quantum error correction operations. The cryogenic classical superconducting circuit 1214 receives the measurements data from reading the syndrome qudits and includes a decoder in FIG. 1 that processes the received information in the measurements data to obtain information on errors in the quantum computing performed by the quantum processor and generates a recovery operation for reconstructing quantum information of the qudits to reduce the errors in the quantum computing.

The quantum correction gadget 1200 may include a cryogenic device 1212 that is designed to provide different cryogenic stages at different cryogenic temperatures. The quantum processor 1210 is cooled by the cryogenic device 1212 at a low cryogenic temperature desirable or suitable for operating qudits. In some implementations, the cryogenic classical superconducting circuit 1214 that contains the decoder may be separated from the quantum processor 1210 and may be kept in the cryogenic device 1212 at a cryogenic temperature higher than that of the quantum processor 1210 such as 100 mK, 600 mK, 3K or 4K. In other implementations, the cryogenic classical superconducting circuit 1214 that contains the decoder may be kept in the cryogenic device 1212 at the same cryogenic stage as the quantum processor 1210 and at the same cryogenic temperature (e.g., tens of mK). The cryogenic device 1212 may be of various types. In one embodiment, the cryogenic device 1212 includes a cryogenic platform capable of reaching the required low temperature for operation of qudits. In another embodiment, the cryogenic device 1212 includes a dilution refrigerator system with different cryogenic stages at different temperatures.

In another embodiment, the cryogenic device 1212 includes a cryocooler system. In another embodiment, the cryogenic device 1212 includes an adiabatic demagnetization refrigerator.

The cryogenic classical superconducting circuit 1214 with the one or more decoders as part of the quantum correction gadget 1200 may be implemented by various suitable cryogenic classical superconducting circuits, including, for example, the cryogenic classical superconducting circuit 100 in FIG. 1.

The cryogenic classical superconducting circuit 1214 may be structured and coupled to the quantum processor 1210 act as a classical coprocessor to the quantum processor 1210. The cryogenic classical superconducting circuit 1214 is cooled by the same cryogenic device 1212 enabling for minimization of the communication lag (or time latency) between the quantum processor 1210 and the cryogenic classical superconducting circuit 1214. It will be appreciated that the information travels at the speed of electromagnetic wave in the medium which is a finite value. The reduction in the travelled distance between modules reduces the communication lag.

The cryogenic classical superconducting circuit 1214 includes at least one function approximator for at least one decoder of quantum error correcting codes 1216. The function approximator for a decoder 1 of quantum error correcting codes 1216 may be of various types such as any function approximator disclosed elsewhere herein. The decoder of quantum error correcting codes 1216 may be of various types such as any decoder disclosed elsewhere herein.

The quantum correction gadget 1200 may include a logical qudit. The logical qudit includes a classical-quantum interface between the cryogenic classical superconducting circuit 1214 and the quantum processor 1210. It will be appreciated that the logical qudit includes a quantum error correction scheme which includes at least one data qudit and at least one syndrome extraction circuit. Each syndrome extraction circuit includes at least one syndrome qudit. The operation of the error correction scheme includes at least (1) at least one iteration of each syndrome extraction circuit, the syndrome extraction circuit includes preparation of syndrome, execution of gates, and measurement of syndrome; (2) communication of the measurement readouts to the decoder; (3) the decoder proposing a recovery operation; (4) the recovery operation may either be immediately applied to the data qudits, or stored for later use.

The quantum correction gadget 1200 may include n copies of the logical qudits disclosed herein.

In the embodiment of the topological error correcting code, the data qudits are laid out on a surface which includes one or more faces, called plaquettes. Each plaquette includes one or more syndrome extraction circuits.

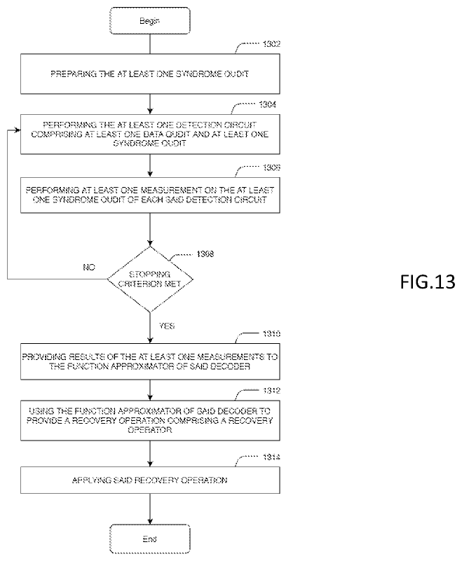

Now referring to FIG. 13, there is shown a flowchart of an embodiment of a method for implementing a quantum error correction scheme using the quantum correction gadget 1200 described in FIG. 12. The method includes operations of the logical qudit disclosed herein.

According to processing step 1302 the at least one syndrome qudit is provided and prepared for performing quantum measurements for the quantum error correction operations. It will be appreciated that the at least one syndrome qudit may be prepared in various ways. In the embodiment, wherein the at least one syndrome qudit includes at least one syndrome qubit, the preparation includes applying energy, for example via microwave photons, to the qudit to place it into a superposition of two or more of its states. The qubit in this state can then be entangled with other qudits in the processor, for example one or more data qudits. Entanglement between qudits may be induced by interacting them together in such a way that the final states of the qudits depend on each other. For example, entanglement between two superconducting qudits can be induced by frequency tuning the qudits on resonance with each other and coupling via a capacitance for some fixed time yielding a state-dependent relative phase shift. In the embodiment wherein the at least one syndrome qudit includes at least one multi-level quantum system, the preparation may include the same method as described above.

According to processing operation 1304 the syndrome extraction circuit is performed. The syndrome extraction circuit includes at least one data qudit and at least one syndrome qudit. The operation of each syndrome extraction circuit includes at least (1) preparation of one or more syndrome qudits in a desired initial state, (2) application of two-qudit gates such as CNOT (in the embodiment of qubits) between pairs among the data qudits, syndrome qudits, and (3) measurement of the syndrome in a desired basis. FIG. 3 of Chamberland, C., Ronagh, P., arXiv:1802.06441 (2018) depicts the syndrome extraction circuit for the rotated surface code. FIG. 3 of Chamberland, C. et al, arXiv:1911.00355 (2020) depicts the syndrome extraction circuit for the triangular color code.

Still referring to FIG. 13 and according to processing step 1306 at least one measurement is performed on the at least one syndrome qudit of each of the at least one syndrome extraction circuit.

According to processing step 1308 if the stopping criterion is met the method proceeds to processing step 1310. If the stopping criterion is not met the processing steps 1304 and 1306 are repeated. It will be appreciated that the stopping criterion may be of various types. In one embodiment, the stopping criterion is that the processing steps 1304 and 1306 were repeated a fixed and predetermined number of times.

Still referring to FIG. 13 and according to processing step 1310 the results of the at least one measurement is provided to the function approximator of the decoder of quantum error correcting codes. The cryogenic classical superconducting circuit is operated to implement the function approximator to obtain the results corresponding to the at least one measurement.

According to processing step 1312 a recovery operation is provided using the function approximator. The recovery operation includes a recovery operator.

According to processing step 1314 the recovery operation is applied. It will be appreciated that the recovery operator may be of various types. In one embodiment, the recovery operator is a unitary operator applied to the error correcting code. The recovery operator may include separate unitary operations on each individual data qubit, for example a single-qubit Pauli X, Y, or Z operations. In an alternative embodiment, the recovery operator additionally includes a change of basis on a Pauli frame. Subsequent gates are passed through this change of basis before being applied, until some future timestep when the unitary operator is applied.

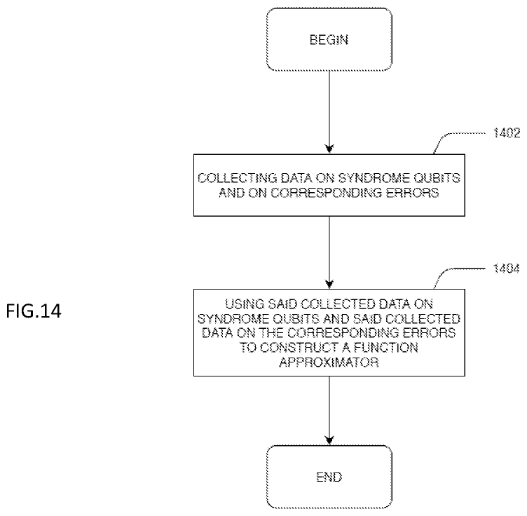

Now referring to FIG. 14 there is show an embodiment of a method for constructing a function approximator for a decoder of quantum error correcting codes. It will be appreciated that the function approximator may be of various types such as any function approximator disclosed elsewhere herein. The function approximator may be any suitable function approximator, such as any function approximator described herein with respect to FIG. 1.

According to processing step 1402 data is collected on the at least one syndrome qudits and on corresponding errors from the error correcting code. It will be appreciated that the data may be collected from simulations of qudits afflicted by a noise channel. It will be further appreciated that the noise channel may include a Pauli noise channel (in the embodiment of qubits), wherein the Pauli noise channel may be depolarizing or dephasing. In one embodiment, the data is collected from simulation of the plurality of qudits performing logical operations. In an alternative embodiment, the data is collected from experimental data, wherein experimental data includes data from the qudits at rest, data from the qudits performing a logical measurement and data from the logical gates.

Still referring to FIG. 14 and according to processing step 1404 the function approximator is constructed using the collected data on the at least one syndrome qudits and the collected data on the corresponding errors. It will be appreciated that in the embodiment wherein the function approximator includes a neural network the construction of the function approximator includes training the neural network. It will be appreciated that the construction of the function approximator may include modifications to accurately model the constraints of the hardware. In one or more embodiments, the modifications may include digitization of the input and output signals, activation functions such as rectified linear unit (ReLU) and sigmoid, and transforming tunable parameters to 8-bit precision. In the embodiment wherein the function approximator includes a neural network, specialized techniques exist to train the neural networks comprising such modifications. (More details can be found in “Binarized Neural Networks: Training Deep Neural Networks with Weights and Activations Constrained to +1 or −1” by Courbariaux, M., Hubara, I., Soudry, D., El-Yaniv, R., Bengio, Y., arXiv:1602.02830 (2016); “Training deep neural networks with low precision multiplications” by Courbariaux, M., Bengio, Y., David J. P., arXiv:1412.7024 (2015); “Deep Learning with Limited Numerical Precision” by Gupta S., Agrawal A., Gopalakrishnan K., Narayanan P, arXiv:1502.02551; and “Quantization and Training of Neural Networks for Efficient Integer-Arithmetic-Only Inference” by Jacob B. et al, arXiv:1712:05877 (2017), which are incorporated by reference as part of the patent specification of this patent document.

### Example of Collecting Data

Data points are generated via simulation for the purpose of training the function approximator and benchmarking the logical error rate of the QEC procedure. The generation of a single data point is as follows. The process for the syndrome extraction circuit and measurement circuit of the Z-stabilizer type is described below; it is analogous for the X-stabilizer circuit. Herein, a code distance d is fixed. All qubit measurements result in a 0 or 1 readout, and therefore the input coordinate is a two-dimensional 0-1 array of size (N_rounds, # syndrome qubits), while the output coordinate is a one-dimensional 0-1 array of size (# data qubits).
A parameter N_rounds is chosen.
A quantum circuit is constructed in simulation which includes, in sequence.
   Preparation of the data qubits in the |0> state.
   N_rounds iterations of the Z-stabilizer circuit as shown in FIGS. 3 and 4 of the above referenced Chamberland article.
The above quantum circuit is passed through a depolarizing noise channel to create a noisy version of the circuit. This depolarizing noise channel is given five separate parameters for the noise strength associated to qubit preparation, one-qubit gates, two-qubit gates, idle qubits, and qubit measurement.
This noisy circuit is then executed in simulation, yielding for each syndrome qubit a sequence of N_rounds measurement readouts. This array of size (N_rounds, #syndrome qubits) is the input coordinate of the data point.
The data qubits are measured perfectly at the end of the noisy circuit. The readout vector of size (#data qubits) is the output coordinate of the data point.

The above process is repeated many times with different random seeds used for the depolarizing noise channel and different random seeds used for the circuit execution, to obtain a large number of data points.

Therefore, various implementations of features of the disclosed technology can be made based on the above disclosure, including the examples listed below.

Example 1. A cryogenic classical superconducting circuit functioning at cryogenic temperatures includes a function approximator for a decoder of quantum error correcting codes, wherein the decoder comprises a plurality of nodes, a plurality of interconnects between nodes of the plurality of nodes for distributing pulses between the nodes, and a plurality of weights representative of the function approximator parameters, wherein each node of the plurality of nodes comprises: a receiver section to receive at least one pulse comprising a magnetic flux, current, or voltage; a processing core to process the received pulse; and a transmitter section to transmit the processed pulse.

Example 2. The cryogenic classical superconducting circuit as in Example 1, includes mixed-signal digital and analogue Josephson junction superconducting electronics comprising magnetic junctions and quantum phase slip devices.

Example 3. The cryogenic classical superconducting circuit as in Example 2, wherein the Josephson junction superconducting electronics comprises digital and mixed-signal quantum flux families comprising energy efficient rapid single flux quantum (ERSFQ), energy efficient single flux quantum (eSFQ), adiabatic quantum flux parametron (AQFP), reciprocal quantum logic (RQL), rapid single flux quantum (RSFQ), SFQuClass, or superconducting quantum interface device (SQUID, Bi-SQUID, nSQUID).

Example 4. The cryogenic classical superconducting circuit as in Examples 1-3, wherein each node is configured to operate at analog, digital or analog-digital mode.

Example 5. The cryogenic classical superconducting circuit as in Example 4, wherein the nodes are arranged in layers, further wherein the receiver section of the nodes in the first layer and the transmitter section in the last layer operate at digital mode; and the nodes in other layers operate at analog mode.

Example 6. The cryogenic classical superconducting circuit as in Example 1, wherein the nodes are coupled by interconnects that are analog, digital or hybrid of analog and digital.

Example 7. The cryogenic classical superconducting circuit as in Example 1, wherein the nodes are coupled by interconnects that are operated synchronously or asynchronously.

Example 8. The cryogenic classical superconducting circuit as in Example 1, wherein the decoder further comprises at least one amplifier to amplify a signal.

Example 9. The cryogenic classical superconducting circuit as in Example 1, wherein at least one weight of the plurality of weights comprises a fixed coupling comprising a magnetic coupling, a capacitive coupling, or a resistive coupling.

Example 10. The cryogenic classical superconducting circuit as in Example 1, wherein at least one weight of the plurality of weights comprises a variable coupling comprising a magnetic coupling, a capacitive coupling, a galvanic coupling or a resistive coupling.

Example 11. The cryogenic classical superconducting circuit as in Example 9, wherein the magnetic coupling comprises a transformer; further wherein different coupling strengths are used for different input pulses in a transformer to represent the weights of the plurality of weights; further wherein fixed magnetic coupling is proportional to the weight.

Example 12. The cryogenic classical superconducting circuit as in Example 9, wherein the resistive coupling comprises a voltage divider; further wherein different coupling strengths are used for different input pulses in the voltage divider to represent the weights of the plurality of weights; further wherein fixed resistive coupling is proportional to the weight.

Example 13. The cryogenic classical superconducting circuit as in Example 10, wherein the weights of the plurality of weights are represented via at least one of generating a number of the single flux quantum (SFQ) pulses proportional to the weight, generating pulse rate proportional to the weight and generating pulses of strength proportional to the weight.

Example 14. The cryogenic classical superconducting circuit as in Example 2, wherein the Josephson junction superconducting electronics comprises a superconducting quantum interface device (SQUID); at least one of the number of generated pulses, the pulse rate or the pulses strength is varied by changing the bias current or the critical current of the superconducting quantum interface device (SQUID).

Example 15. The cryogenic classical superconducting circuit as in Example 9, wherein the processing core comprises at least one storage loop for storing the magnetic flux; and the magnetic flux is cleared using a resistor, a SQUID, or a command pulse that could be a clock.

Example 16. The cryogenic classical superconducting circuit as in Example 1, wherein the interconnect between two nodes of the plurality of nodes is electrical, magnetic, or photonic.

Example 17. The cryogenic classical superconducting circuit as claimed in any of the claims 1-16, wherein the interconnect between at least two nodes of the plurality of nodes is parallel or serial.

Example 18. The cryogenic classical superconducting circuit as claimed in any of the Examples 1-16, wherein the interconnect between two nodes of the plurality of nodes is electrical using a Josephson transmission line (JTL) or a passive transmission line (PTL).

Example 19. The cryogenic classical superconducting circuit as in Example 1, wherein the pulses between the nodes are generated using line drivers wherein each the pulse creates at least one pulse.

Example 20. The cryogenic classical superconducting circuit as in Example 1, wherein the function approximator for a decoder of quantum error correcting codes comprises a neural network; further wherein the neural network parameters and activations are represented by the decoder nodes and weights; further wherein the neural network activations are implemented using the nodes processing cores.

Example 21. The cryogenic classical superconducting circuit as in Example 20, wherein the activations comprise sigmoid and rectified linear unit (ReLU) activation functions.

Example 22. The cryogenic classical superconducting circuit as in Example 20, wherein the neural network comprises a recurrent neural network, a deep neural network, a feed forward neural network, a convolutional neural network, a Hopfield network, a Boltzmann machine, or a graphical model.

Example 23. The cryogenic classical superconducting circuit as in Example 1, wherein the function approximator for a decoder of quantum error correcting codes comprises at least one neural network and at least one linear function approximator.

Example 24. The cryogenic classical superconducting circuit as in Example 1, wherein at least one weight of the plurality of weights is programmable.

Example 25. The cryogenic classical superconducting circuit as in Example 1, wherein the function approximator is programmable using an input from a user.

Example 26. The cryogenic classical superconducting circuit as in Example 1, wherein the function approximator for a decoder of quantum error correcting codes comprises a regression unit, a classifier, a decision tree, or a random forest.

Example 27. A system for quantum computing and capable of quantum error correction includes a cryogenic device structured to include different cryogenic stages at different cryogenic temperatures; a quantum processor comprising a plurality of qudits to perform quantum computing and coupled to and cooled by the cryogenic device at a desired cryogenic temperature for proper operations of the qudits, the plurality of qudits comprising data qudits to encode quantum information for quantum computing and syndrome qudits to interact with the data qudits to provide measurements, wherein the plurality of qudits provides an error correcting code for correcting quantum errors; and a cryogenic classical superconducting circuit coupled to and cooled by the cryogenic device, and further coupled to receive information on the measurements from the syndrome qudits, and structured to include a decoder of the quantum error correcting code to process the received information on the measurements from the syndrome qudits and to generate a recovery operation for data qudits to reduce errors in the quantum computing, wherein the cryogenic classical superconducting circuit is coupled as a classical coprocessor to the quantum processor to reduce a communication lag between the quantum processor and the cryogenic classical superconducting circuit.

Example 28. The system as in Example 27, wherein the error correcting code is a topological error correcting code.

Example 29. The system as in Example 27, wherein the error correction procedure on the topological error correcting code comprises parity check operations on the plurality of the qudits comprising plaquettes.

Example 30. The system as in Example 28, wherein the topological code comprises a toric code, a surface code, a rotated surface code, a colour code, a triangular colour code, or a heavy hexagonal code.

Example 31. The system as in Example 27, wherein the cryogenic device comprises a cryogenic platform capable of reaching the required temperature for operation of qudits.

Example 32. The system as in Example 27, wherein the cryogenic device comprises a dilution refrigerator system, a cryocooler system, or an adiabatic demagnetisation refrigerator.

Example 33. A method for implementing a quantum error correction scheme using the system as in Example 27 includes (i) preparing the at least one syndrome qudit; (ii) performing the at least one syndrome extraction circuit comprising at least one data qudit and at least one syndrome qudit; (iii) performing at least one measurement on the at least one syndrome qudit of each the syndrome extraction circuit; (iv) providing results of the at least one measurement to the function approximator of the detector; (v) using the function approximator of the decoder to provide a recovery operation comprising a recovery operator; and (vi) applying the recovery operation.

Example 34. The method as in Example 33, wherein the recovery operator is a unitary operator applied to the error correcting code.

Example 35. The method as in Example 33, wherein the recovery operator is a change of basis on a Pauli frame.

Example 36. The method as in Example 33, wherein the recovery operator is an identity operator.

Example 37. The method as in Example 33, wherein steps in (ii)-(iv) are repeated at least one time.

Example 38. A method for constructing the function approximator for the decoder of the system as in Example 27 includes collecting data on the at least one syndrome qudits and on corresponding errors from the error correcting code; and using the collected data on the at least one syndrome qudits and the collected data on the corresponding errors to construct the function approximator.

Example 39. The method as in Example 38, wherein (b) comprises training a neural network.

Example 40. The method as in Example 38, wherein the data is collected from simulation of qudits afflicted by a noise channel.

Example 41. The method as in Example 40, wherein the noise channel comprises a Pauli noise channel; further wherein the Pauli noise channel is depolarizing or dephasing.

Example 42. The method as in Example 38, wherein the data is collected from simulation of the plurality of qudits performing logical operations.

Example 43. The method as in Example 38 wherein the data is collected from experimental data, wherein experimental data comprises data from qudits at rest, data from qudits performing a logical measurement and data from logical gates.

Example 44. The system as in Example 27 for a fault tolerant quantum computing incudes a plurality of logical qudits each comprising a classical-quantum interface between the cryogenic classical superconducting circuit and the quantum processor, the logical qudit comprising quantum error correction scheme, the plurality of logical qudits for performing quantum computing.

Example 45. The system as in Example 27 wherein the quantum processor comprises at least one syndrome extraction circuit.

Example 46. The system as in Example 27, wherein the cryogenic classical superconducting circuit and the quantum processor are coupled to different cryogenic stages of the cryogenic device and thus are cooled at different cryogenic temperatures.

Example 47. The system as in Example 27, wherein the cryogenic classical superconducting circuit and the quantum processor are coupled to a common cryogenic stage of the cryogenic device and thus are cooled at a common cryogenic temperature.

Example 48. A quantum computing system includes a quantum processor comprising a plurality of physical qudits each capable of exhibiting different quantum states, the plurality of physical qudits structured to perform quantum computing and to comprise a plurality of data qudits to perform quantum computing and a plurality of syndrome qudits located amongst the data qudits to interact with the data qudits to provide measurements of quantum states of the syndrome qudits that are indicative of quantum errors in the quantum processor; qudit readout circuits coupled to the quantum processor to interact with the syndrome qudits and to produce readout signals representing measurements of quantum states of the syndrome qudit; a cryogenic classical superconducting circuit coupled to receive information of the readout signals representing measurements of quantum states of the syndrome qudits, the cryogenic classical superconducting circuit structured to include a decoder that processes the received information to obtain information on quantum errors in the quantum processor and generates a recovery operation for reconstructing quantum information of the qudits to reduce the quantum errors; and a cryogenic system coupled to enclose the quantum processor, the qudit readout circuits and the cryogenic classical superconducting circuit at desired cryogenic temperatures, respectively, wherein the cryogenic classical superconducting circuit and the quantum processor are positioned relative to each other to enable fast communications between the cryogenic classical superconducting circuit and the quantum processor with a reduced communication lag.

Example 49. The system as in Example 27 or 48, wherein the decoder in the cryogenic classical superconducting circuit includes a neural network which includes: a plurality of nodes coupled to form different layers of nodes as part of the neural network; and a plurality of interconnects between nodes of the different layers of nodes to provide signaling between nodes of the different layers of nodes, each node structured to apply weights on signaling between nodes of the different layers of nodes.

Example 50. The system as in Example 27 or 48, wherein the cryogenic classical superconducting circuit is configured as in any one of Examples 1-26.

Example 51. The system as in Example 48, wherein the quantum processor is operable to prepare the syndrome qudits in desired initial states, to cause quantum mechanical interactions between data qudits and syndrome qudits, and wherein the qudit readout circuits are operated to obtain measurements of the syndrome qudits in a desired basis.

Example 52. The system as in Example 48, wherein the cryogenic classical superconducting circuit and the quantum processor are coupled to different cryogenic stages of the cryogenic device and thus are cooled at different cryogenic temperatures.

Example 53. The system as in Example 48, wherein the cryogenic classical superconducting circuit and the quantum processor are coupled to a common cryogenic stage of the cryogenic device and thus are cooled at a common cryogenic temperature.

The publications, patents, and patent applications cited in this patent document are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples are described and other implementations, enhancements and variations can be made based on what is described and illustrated in this patent document.

1. A cryogenic classical superconducting circuit functioning at cryogenic temperatures comprising a function approximator for a decoder of quantum error correcting codes, wherein the decoder comprises a plurality of nodes, a plurality of interconnects between nodes of the plurality of nodes for distributing pulses between the nodes, and a plurality of weights representative of the function approximator parameters, wherein each node of the plurality of nodes comprises:
a receiver section to receive at least one pulse comprising a magnetic flux, current, or voltage;
a processing core to process the received pulse; and
a transmitter section to transmit the processed pulse.

2. The cryogenic classical superconducting circuit as in claim 1 comprising mixed-signal digital and analogue Josephson junction superconducting electronics comprising magnetic junctions and quantum phase slip devices.

3. The cryogenic classical superconducting circuit as in claim 2, wherein the Josephson junction superconducting electronics comprises digital and mixed-signal quantum flux families comprising energy efficient rapid single flux quantum (ERSFQ), energy efficient single flux quantum (eSFQ), adiabatic quantum flux parametron (AQFP), reciprocal quantum logic (RQL), rapid single flux quantum (RSFQ), SFQuClass, or superconducting quantum interface device (SQUID, Bi-SQUID, nSQUID).

4. The cryogenic classical superconducting circuit as in claims 1-3, wherein each node is configured to operate at analog, digital or analog-digital mode.

5. The cryogenic classical superconducting circuit as in claim 4, wherein the nodes are arranged in layers, further wherein the receiver section of the nodes in the first layer and the transmitter section in the last layer operate at digital mode; and the nodes in other layers operate at analog mode.

6. The cryogenic classical superconducting circuit as in claim 1, wherein the nodes are coupled by interconnects that are analog, digital or hybrid of analog and digital.

7. The cryogenic classical superconducting circuit as in claim 1, wherein the nodes are coupled by interconnects that are operated synchronously or asynchronously.

8. The cryogenic classical superconducting circuit as in claim 1, wherein the decoder further comprises at least one amplifier to amplify a signal.

9. The cryogenic classical superconducting circuit as in claim 1, wherein at least one weight of the plurality of weights comprises a fixed coupling comprising a magnetic coupling, a capacitive coupling, or a resistive coupling.

10. The cryogenic classical superconducting circuit as in claim 1, wherein at least one weight of the plurality of weights comprises a variable coupling comprising a magnetic coupling, a capacitive coupling, a galvanic coupling or a resistive coupling.

11. The cryogenic classical superconducting circuit as in claim 9, wherein the magnetic coupling comprises a transformer; wherein different coupling strengths are used for different input pulses in a transformer to represent the weights of the plurality of weights; and wherein fixed magnetic coupling is proportional to the weight.

12. The cryogenic classical superconducting circuit as in claim 9, wherein the resistive coupling comprises a voltage divider; further wherein different coupling strengths are used for different input pulses in the voltage divider to represent the weights of the plurality of weights; further wherein fixed resistive coupling is proportional to the weight.

13. The cryogenic classical superconducting circuit as in claim 10, wherein the weights of the plurality of weights are represented via at least one of generating a number of the single flux quantum (SFQ) pulses proportional to the weight, generating pulse rate proportional to the weight and generating pulses of strength proportional to the weight.

14. The cryogenic classical superconducting circuit as in claim 2, wherein the Josephson junction superconducting electronics comprises a superconducting quantum interface device (SQUID); at least one of the number of generated pulses, the pulse rate or the pulses strength is varied by changing the bias current or the critical current of the superconducting quantum interface device (SQUID).

15. The cryogenic classical superconducting circuit as in claim 9, wherein the processing core comprises at least one storage loop for storing the magnetic flux; and the magnetic flux is cleared using a resistor, a SQUID, or a command pulse that could be a clock.

16. The cryogenic classical superconducting circuit as in claim 1, wherein the interconnect between two nodes of the plurality of nodes is electrical, magnetic, or photonic.

17. The cryogenic classical superconducting circuit as in claim 1, wherein the interconnect between at least two nodes of the plurality of nodes is parallel or serial.

18. The cryogenic classical superconducting circuit as in claim 1, wherein the interconnect between two nodes of the plurality of nodes is electrical using a Josephson transmission line (JTL) or a passive transmission line (PTL).

19. The cryogenic classical superconducting circuit as in claim 1, wherein the pulses between the nodes are generated using line drivers wherein each the pulse creates at least one pulse.

20. The cryogenic classical superconducting circuit as in claim 1, wherein the function approximator for a decoder of quantum error correcting codes comprises a neural network; further wherein the neural network parameters and activations are represented by the decoder nodes and weights; further wherein the neural network activations are implemented using the nodes processing cores.

21. The cryogenic classical superconducting circuit as in claim 20, wherein the activations comprise sigmoid and rectified linear unit (ReLU) activation functions.

22. The cryogenic classical superconducting circuit as in claim 20, wherein the neural network comprises a recurrent neural network, a deep neural network, a feed forward neural network, a convolutional neural network, a Hopfield network, a Boltzmann machine, or a graphical model.

23. The cryogenic classical superconducting circuit as in claim 1, wherein the function approximator for a decoder of quantum error correcting codes comprises at least one neural network and at least one linear function approximator.

24. The cryogenic classical superconducting circuit as in claim 1, wherein at least one weight of the plurality of weights is programmable.

25. The cryogenic classical superconducting circuit as in claim 1, wherein the function approximator is programmable using an input from a user.

26. The cryogenic classical superconducting circuit as in claim 1, wherein the function approximator for a decoder of quantum error correcting codes comprises a regression unit, a classifier, a decision tree, or a random forest.

27. A system for quantum computing and capable of quantum error correction, the system comprising:
(a) a cryogenic device structured to include different cryogenic stages at different cryogenic temperatures;
(b) a quantum processor comprising a plurality of quantum devices with two or more different quantum states (“qudits”) to perform quantum computing and coupled to and cooled by the cryogenic device at a desired cryogenic temperature for proper operations of the qudits, the plurality of qudits comprising data qudits to encode quantum information for quantum computing and syndrome qudits to interact with the data qudits to provide measurements, wherein the plurality of qudits provides an error correcting code for correcting quantum errors; and
(c) a cryogenic classical superconducting circuit coupled to and cooled by the cryogenic device, and further coupled to receive information on the measurements from the syndrome qudits, and structured to include a decoder of the quantum error correcting code to process the received information on the measurements from the syndrome qudits and to generate a recovery operation for data qudits to reduce errors in the quantum computing, wherein the cryogenic classical superconducting circuit is coupled as a classical coprocessor to the quantum processor to reduce a communication lag between the quantum processor and the cryogenic classical superconducting circuit.

28. The system as in claim 27, wherein the error correcting code is a topological error correcting code.

29. The system as in claim 27, wherein the error correction procedure on the topological error correcting code comprises parity check operations on the plurality of the qudits comprising plaquettes.

30. The system as in claim 28, wherein the topological code comprises a toric code, a surface code, a rotated surface code, a colour code, a triangular colour code, or a heavy hexagonal code.

31. The system as in claim 27 comprising a plurality of logical qudits each comprising a classical-quantum interface between the cryogenic classical superconducting circuit and the quantum processor, the logical qudit comprising quantum error correction scheme, the plurality of logical qudits for performing quantum computing.

32. The system as in claim 27 wherein the quantum processor comprises at least one syndrome extraction circuit.

33. A method for implementing a quantum error correction scheme using the system as in claim 27, the method comprising:
(i) preparing the at least one syndrome qudit;
(ii) performing the at least one syndrome extraction circuit comprising at least one data qudit and at least one syndrome qudit;
(iii) performing at least one measurement on the at least one syndrome qudit of each the syndrome extraction circuit;
(iv) providing results of the at least one measurement to the function approximator of the detector;
(v) using the function approximator of the decoder to provide a recovery operation comprising a recovery operator; and
(vi) applying the recovery operation.

34. The method as in claim 33, wherein the recovery operator is a unitary operator applied to the error correcting code.

35. The method as in claim 33, wherein the recovery operator is a change of basis on a Pauli frame.

36. The method as in claim 33, wherein the recovery operator is an identity operator.

37. The method as in claim 33, wherein steps in (ii)-(iv) are repeated at least one time.

38. A method for constructing the function approximator for the decoder of the system as in claim 27, the method comprising:
(a) collecting data on the at least one syndrome qudits and on corresponding errors from the error correcting code; and
(b) using the collected data on the at least one syndrome qudits and the collected data on the corresponding errors to construct the function approximator.

39. The method as in claim 38, wherein (b) comprises training a neural network.

40. The method as in claim 38, wherein the data is collected from simulation of qudits afflicted by a noise channel.

41. The method as in claim 40, wherein the noise channel comprises a Pauli noise channel; further wherein the Pauli noise channel is depolarizing or dephasing.

42. The method as in claim 38, wherein the data is collected from simulation of the plurality of qudits performing logical operations.

43. The method as in claim 38 wherein the data is collected from experimental data, wherein experimental data comprises data from qudits at rest, data from qudits performing a logical measurement and data from logical gates.
